(19) United States
(12) Patent Application Publication
(10) Pub. No.: US 2023/0290676 A1
(43) Pub. Date: Sep. 14, 2023

(54) Self Aligned Multiple Patterning Method

(71) Applicant: Tokyo Electron Limited, Tokyo (JP)

(72) Inventors: David Power, Albany, NY (US); David Conklin, Albany, NY (US); Jodi Grzeskowiak, Schenectady, NY (US); Michael Murphy, Albany, NY (US)

(21) Appl. No.: 17/989,438

(22) Filed: Nov. 17, 2022

Related U.S. Application Data
(60) Provisional application No. 63/318,619, filed on Mar. 10, 2022.

(51) Int. Cl. H01L 21/768; H01L 21/033; H01L 21/311

(52) U.S. Cl. CPC H01L 21/76816; H01L 21/0337; H01L 21/31144; H01L 21/76897

(57) ABSTRACT

A method of patterning a substrate, where the method includes: forming first structures over a memorization layer, the first structures including a first row of lines that are parallel with each other and spaced apart from each other; executing a first anti-spacer formation process to form first trenches along sidewalls of the first structures and sidewalls of a first fill material, the first trenches defining a first etch pattern; transferring the first etch pattern into the memorization layer and removing materials above the memorization layer; forming second structures over the memorization layer, the second structures including a second row of lines that are parallel with each other and spaced apart, placement of the second row of lines being shifted relative to the first row of lines; executing a second anti-spacer formation process to form second trenches formed along sidewalls of the second structures and sidewalls of a second fill material, the second trenches defining a second etch pattern; and transferring the second etch pattern into the memorization layer and removing materials above the memorization layer.

### CROSS-REFERENCE TO RELATED APPLICATIONS

This application claims the benefit of U.S. Provisional Application No. 63/318,619, filed on Mar. 10, 2022, which application is hereby incorporated herein by reference.

### TECHNICAL FIELD

The present invention relates generally to methods for patterning a substrate, and, in particular embodiments, to a system and method for self-aligned multiple patterning.

### BACKGROUND

An integrated circuit (IC) is a network of electronic components built as a monolithic structure comprising a stack of patterned layers of various materials. The structure is fabricated by processing a semiconductor substrate through a sequence of patterning levels where, at each level, a patterned layer is formed using photolithography. The component packing density is roughly doubled every two years to reduce cost. To print the smaller features, shorter wavelength (λ) lithography systems were developed. The light source was changed from Hg-vapor lamps for 436 nm, 405 nm, and 365 nm λ to deep ultraviolet (DUV) excimer lasers for 248 nm and 193 nm λ. As given by the Rayleigh criterion, a resolution limited minimum half-pitch (HP) scaled as λ/(4 NA), where NA is numerical aperture. Thus, in theory, HP≥48 nm for λ=193 nm and, even for NA=1.33 (using 193 nm immersion (193i)), HP≥36 nm. Despite that, 193 nm and 193i have supported nodes from 90 nm to 10 nm, patterning pitches below the Rayleigh limit using “multiple patterning” techniques, whereby a multiple of a feature density on a reticle is formed in a material layer. The sub-10 nm nodes, would likely use multiple patterning, along with 13.5 nm extreme ultraviolet (EUV) lithography; hence, more innovation in multiple patterning is desired.

### SUMMARY

A method of patterning a substrate, where the method includes: forming first structures over a memorization layer, the first structures including a first row of lines that are parallel with each other and spaced apart from each other; executing a first anti-spacer formation process to form first trenches along sidewalls of the first structures and sidewalls of a first fill material, the first trenches defining a first etch pattern; transferring the first etch pattern into the memorization layer and removing materials above the memorization layer; forming second structures over the memorization layer, the second structures including a second row of lines that are parallel with each other and spaced apart, placement of the second row of lines being shifted relative to the first row of lines; executing a second anti-spacer formation process to form second trenches formed along sidewalls of the second structures and sidewalls of a second fill material, the second trenches defining a second etch pattern; and transferring the second etch pattern into the memorization layer and removing materials above the memorization layer.

A method of patterning a substrate, where the pattern includes a row of parallel final trenches having a first pitch, and the method includes: forming a first hardmask layer over a layer to be patterned in a substrate; forming, over the first hardmask layer, first stencil trenches having a pitch equal to double the first pitch, each trench of the first stencil trenches having a first width; forming a pattern of first hardmask trenches by etching the first hardmask layer using the first stencil trenches as an etch mask; forming a first block mask over the first hardmask layer, the first block mask covering a portion of the first hardmask trenches to form a first etch pattern over the layer to be patterned; transferring the first etch pattern to the layer to be patterned to form a first group of final trenches and removing the first block mask and the first hardmask layer; and transferring a second etch pattern to the layer to be patterned to form a second group of final trenches, the second group of final trenches and the first group of final trenches collectively forming a pattern of final trenches having the first pitch, and all of the final trenches having the same first width.

A method of designing a reticle set, where the method includes: having a final design including a line-and-space (L/S) pattern having a final pitch; and decomposing the final design into a first reticle design and a second reticle design, the first reticle design and the second reticle design being part of a reticle design for the reticle set for quadruple patterning with anti-spacer self-aligned litho-etch-litho-etch (AS-SALELE) process, the first reticle design configured to pattern a first row of mandrels having a mandrel pitch equal to quadruple the final pitch, and the second reticle design configured to pattern a second row of mandrels having the same mandrel pitch, a placement of the second row of mandrels being shifted relative to the first row of mandrels by a distance equal to the final pitch in a direction parallel to the row of mandrels, the first reticle design and the second reticle design being configured to form a L/S pattern having the final pitch on a substrate.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1F illustrate an example final design and a decomposition of the final design for an anti-spacer self-aligned litho-etch-litho-etch (AS-SALELE) quadruple patterning process, in accordance with some embodiments;

FIGS. 2A-2F illustrate cross-sectional views of a semiconductor device at various intermediate stages of processing in a process flow for an in-diffusion anti-spacer formation process;

FIGS. 3A-3C illustrate cross-sectional views of a semiconductor device at various intermediate stages of processing in a process flow for an out-diffusion anti-spacer formation process;

FIGS. 4A-4I illustrate cross-sectional views and planar views of a semiconductor device at various intermediate stages of processing in a process flow for patterning a substrate using AS-SALELE, in accordance with some embodiment;

FIG. 5 illustrates a flowchart summarizing the embodiment of the process flow illustrated in FIGS. 4A-4I;

FIGS. 6A-6M illustrate cross-sectional views and planar views of a semiconductor device at various intermediate stages of processing in a process flow for patterning a substrate using AS-SALELE, in accordance with some embodiment; and

FIG. 7 illustrates a flowchart summarizing the embodiment of the process flow illustrated in FIGS. 6A-6M.

### DETAILED DESCRIPTION OF ILLUSTRATIVE EMBODIMENTS

The disclosure describes embodiments of a method of patterning a substrate by a litho-etch-litho-etch (LELE) multiple patterning technique, where etch masks comprising anti-spacers, formed self-aligned to patterned mandrels, are utilized. In the anti-spacer formation processes, a peripheral region of a layer is chemically modified such that a solubility of the material in that region is greatly enhanced for some solvent. The modified material having the high solubility is referred to as anti-spacer material. In the embodiments, the anti-spacer material is formed self-aligned to the mandrels and removed selectively in a subsequent process step. The spaces vacated by removing the anti-spacer material form an etch mask are the anti-spacers. The anti-spacers comprise a pattern of trenches, where each trench of the pattern of trenches has a width equal to a thickness of the anti-spacer material formed and removed from a side of the respective mandrel. The multiple patterning technique using self-aligned anti-spacers is referred to as anti-spacer self-aligned LELE (AS-SALELE) in this disclosure. In contrast, in a self-aligned LELE (SALELE) multiple patterning technique, spacers are formed self-aligned to patterned mandrels, and material between spacers are removed. The gaps created by removing material between spacers form an etch mask comprising a pattern of trenches. Each pair of adjacent trenches of the pattern of trenches is separated by one of the spacers. Hence, the linewidth of each of the lines separating adjacent trenches, formed by the SALELE technique, is equal to a width of the spacer. In contrast, the trench width of each of the spaces separating adjacent lines, formed by the AS-SALELE technique, is equal to the thickness of the anti-spacer material.

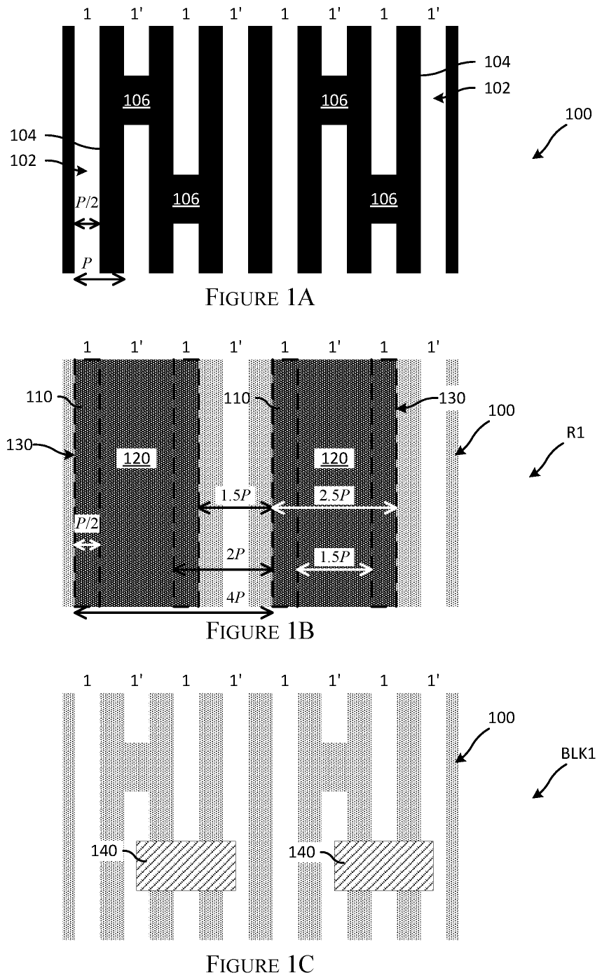

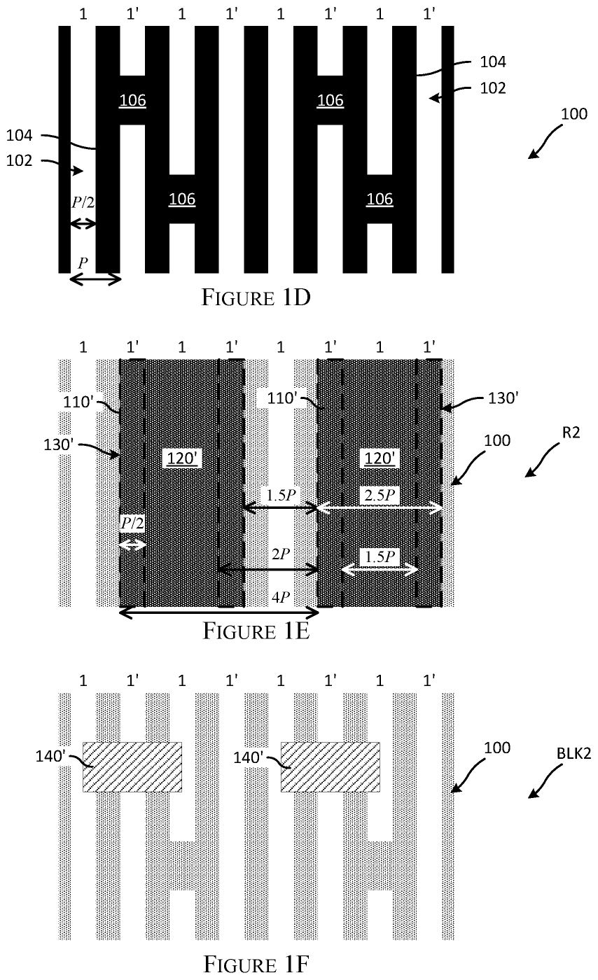

One advantage of using the AS-SALELE technique may be attributed to the use of placing anti-spacer material at the locations of trenches in a final design. The final design refers to the pattern that is eventually etched into a layer to be patterned in the substrate. Consider a final design comprising a line-and space (L/S) pattern having a first pitch, where the first pitch is a final pitch, P, and where each of the trenches (i.e., each of the spaces) has a first width of P/2, where the first width is a final width. In the example final design in this disclosure, the final width is P/2. As explained with reference to FIGS. 1A-1F, the final design may be decomposed into two mandrel reticle designs. Two more reticles are used to form block masks. A block feature is used to terminate a trench. Each mandrel reticle design is a row of mandrels having a mandrel pitch of 4P. In contrast, as known to persons skilled in the art, to pattern the same final design using SALELE, each of the two decomposed reticle designs has features placed at a pitch of 2P. In other words, AS-SALELE provides a quadrupling of feature density, compared to a doubling of feature density provided by SALELE at the same mask count and pitch-walking effect. The larger lithographic pitch implies that pitch walking may be reduced because of less process variations in the lithography processing steps. The larger mandrel pitch (4P) in the decomposition for AS-SALELE leads to wider mandrel lines, hence provides higher patterning accuracy and reduced patterning defects, for example, reduced stochastic defects in patterning with extreme ultraviolet (EUV) lithography.

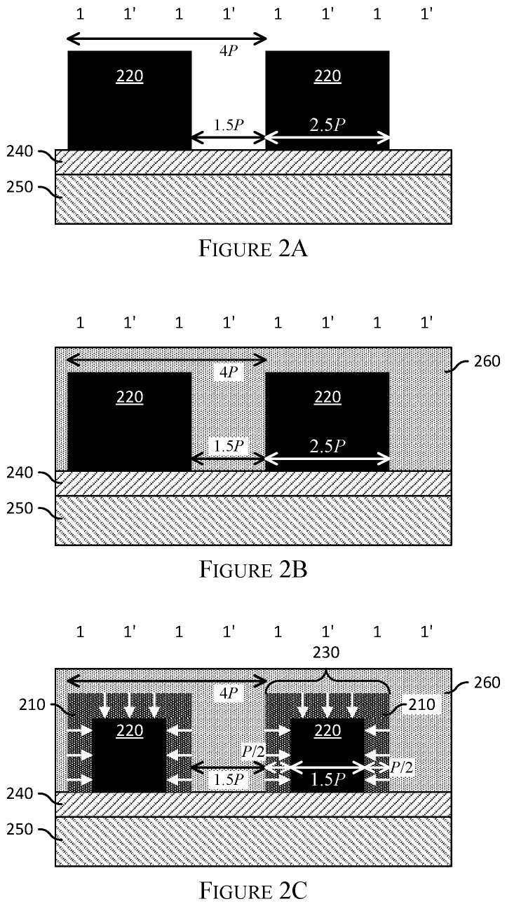

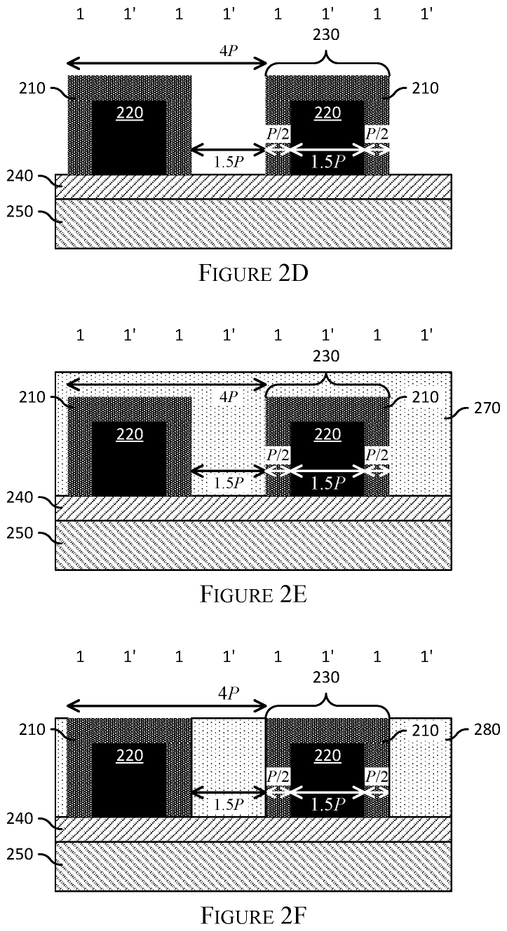

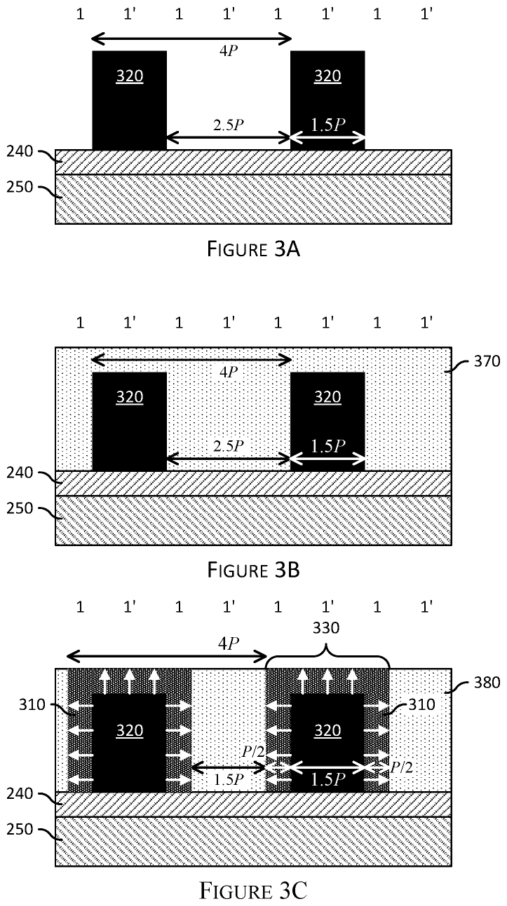

In this disclosure, an example final design and a decomposition of the final design for an AS-SALELE quadruple patterning process is described with reference to FIGS. 1A-1F. Then, two example anti-spacer formation processes are described. In one example, a chemically active species is diffused into the mandrels from an adjacent material and chemically reacted with the mandrel material within a controlled diffusion distance to convert the material there to anti-spacer material. This is an in-diffusion process, described with reference to FIGS. 2A-2F. In the other example, a chemically active species is diffused out of the mandrels into an adjacent material and chemically reacted with the adjacent material within a controlled diffusion distance to convert the material there to anti-spacer material. This is an out-diffusion process, described with reference to FIGS. 3A-3C. Either the in-diffusion or the out-diffusion anti-spacer formation process may be utilized in process flows for AS-SALELE quadruple patterning, as explained in detail further below.

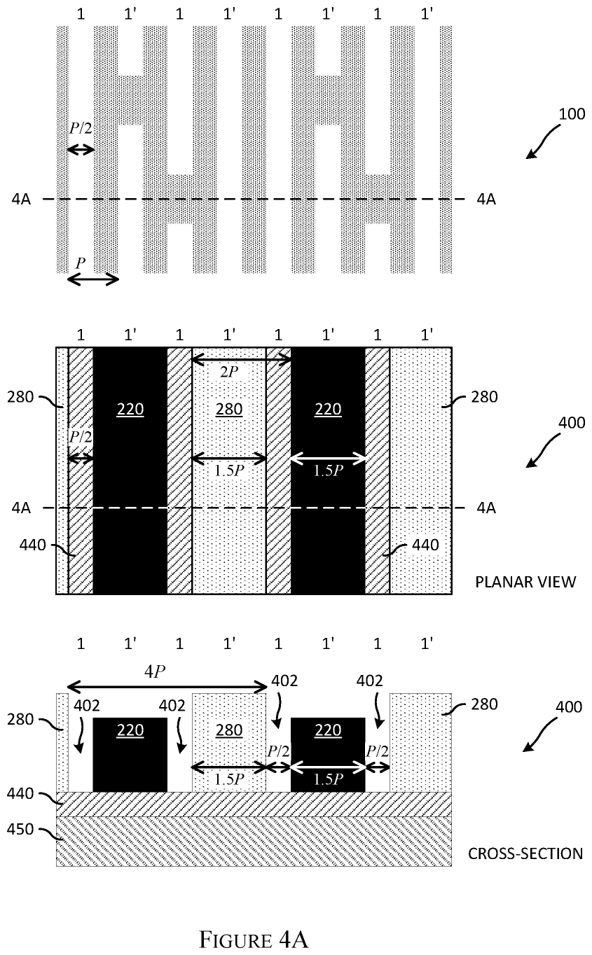

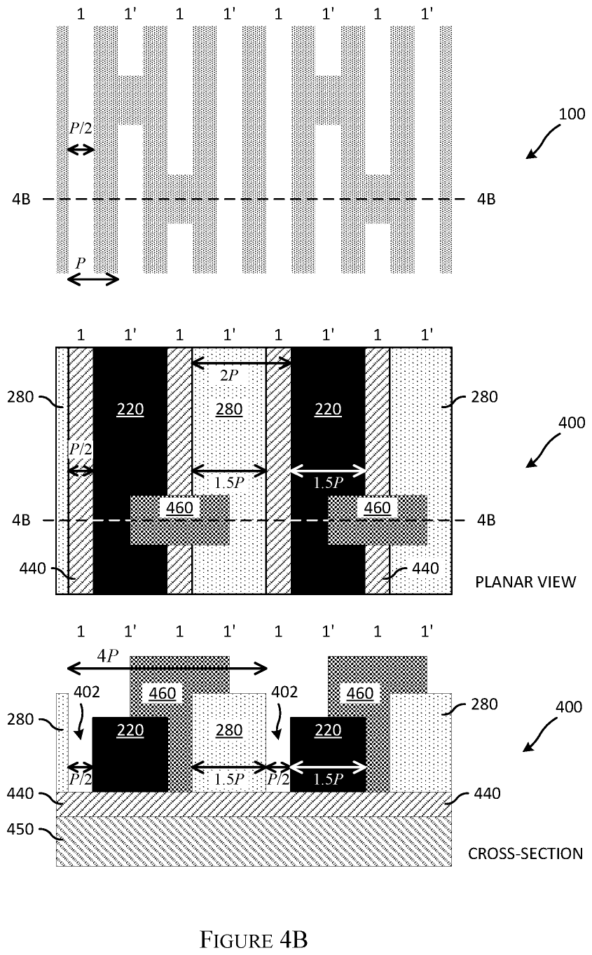

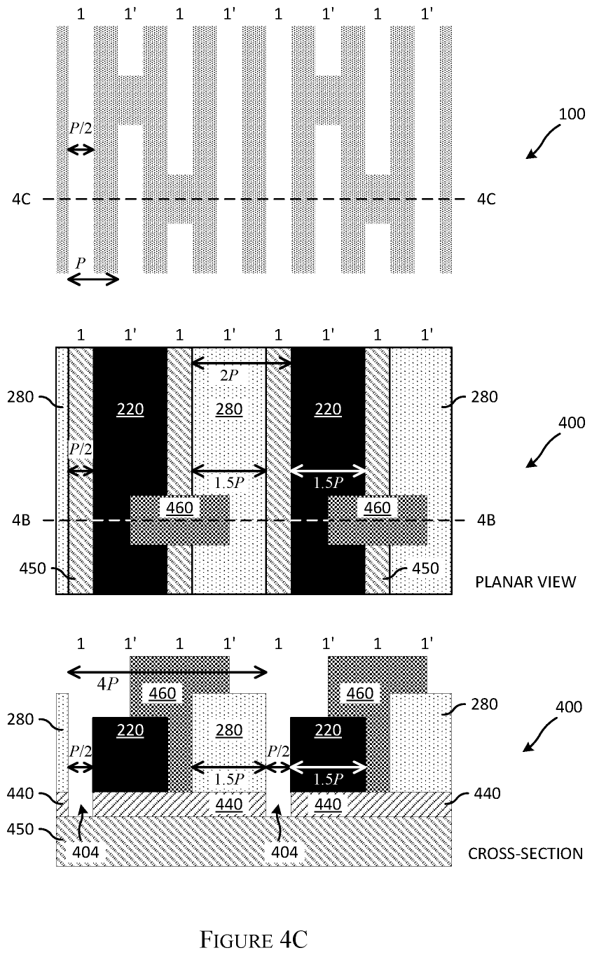

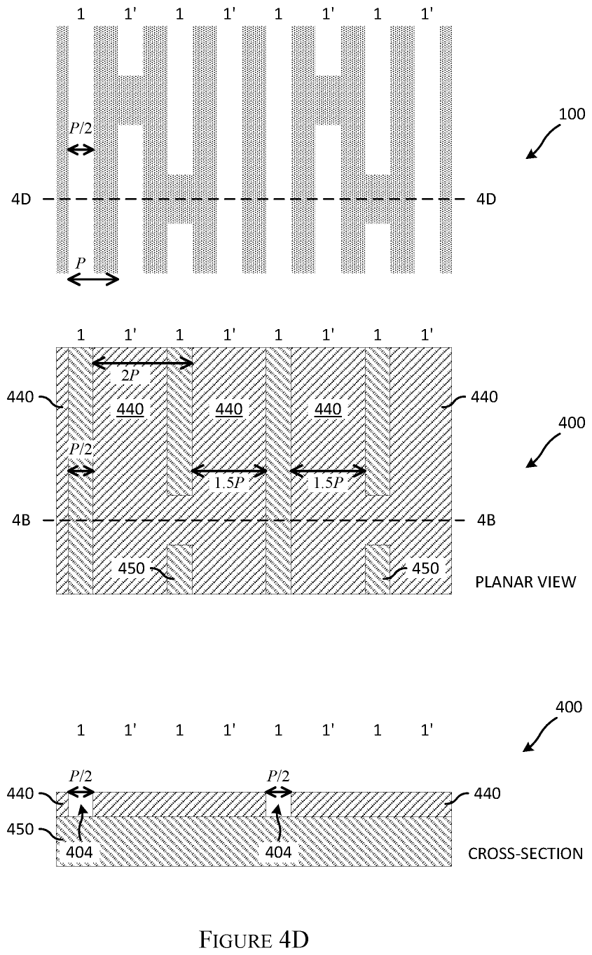

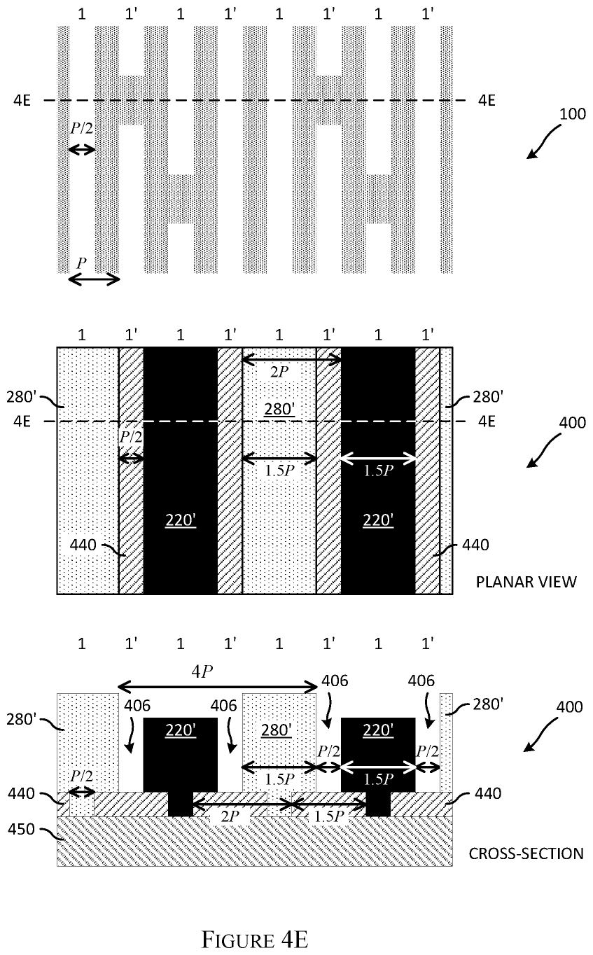

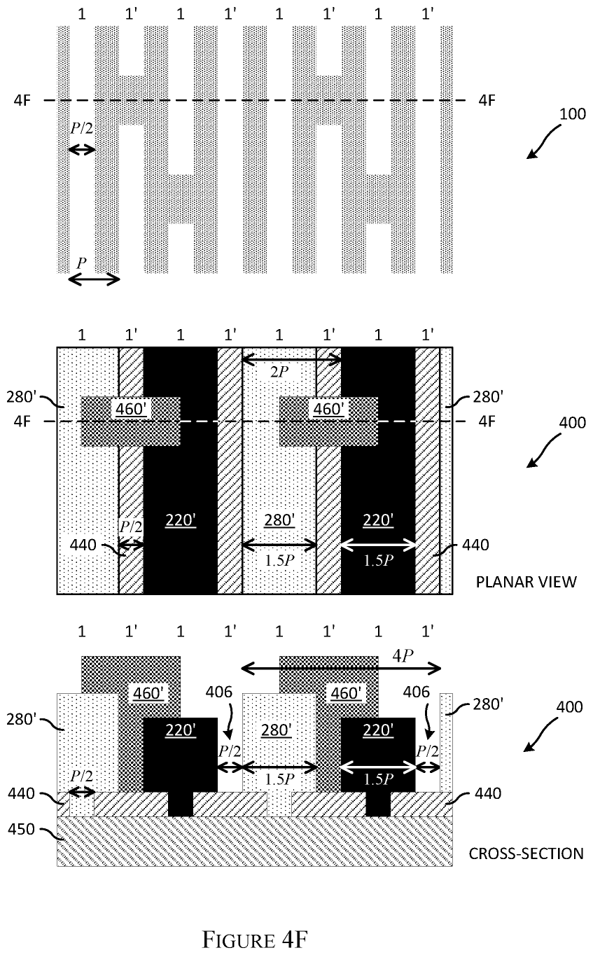

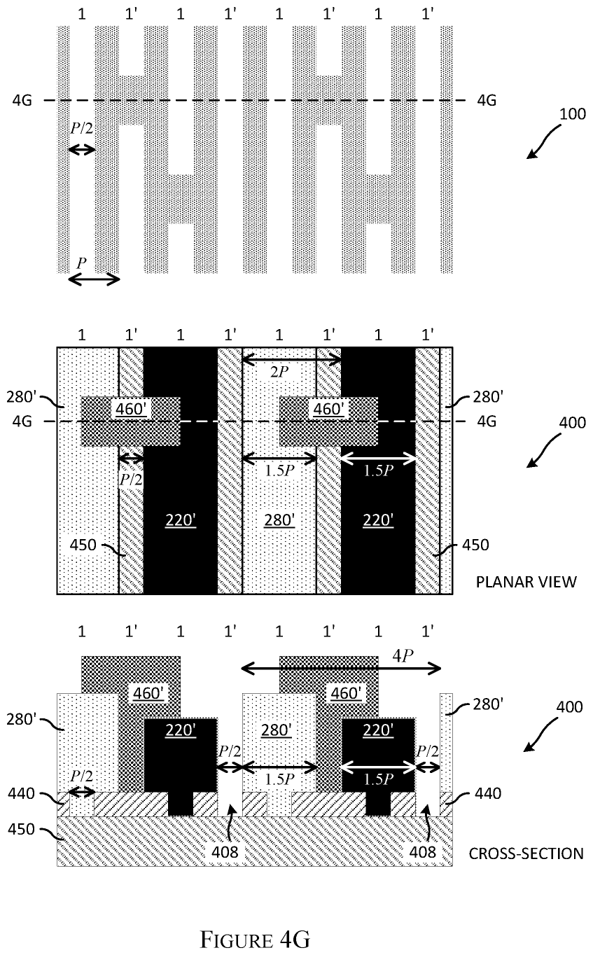

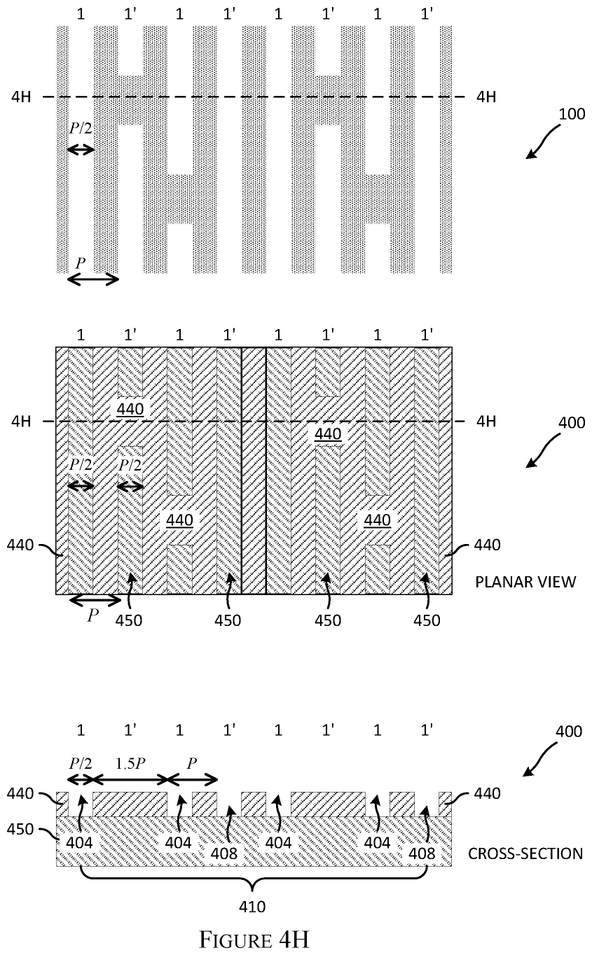

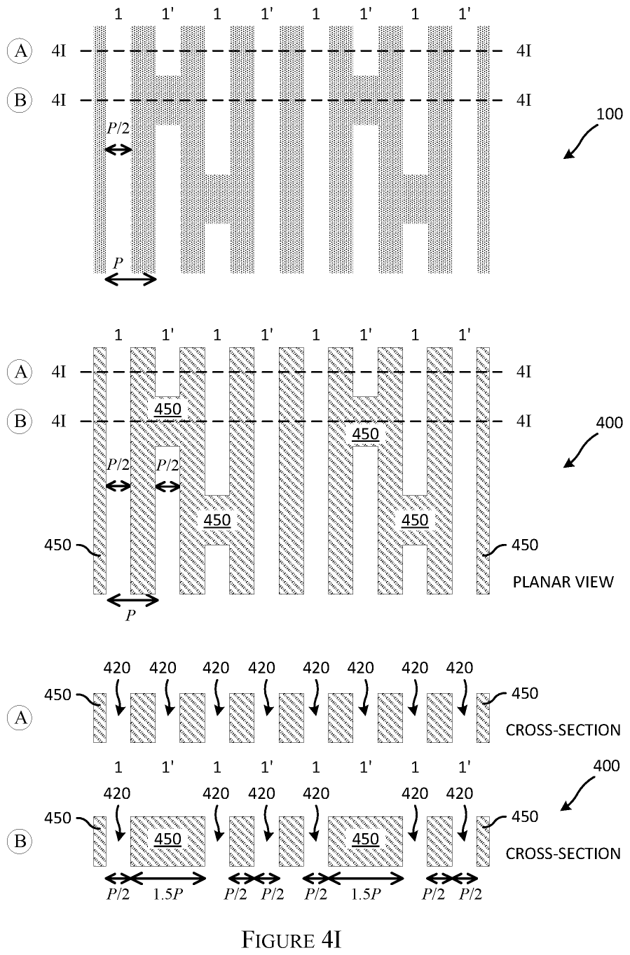

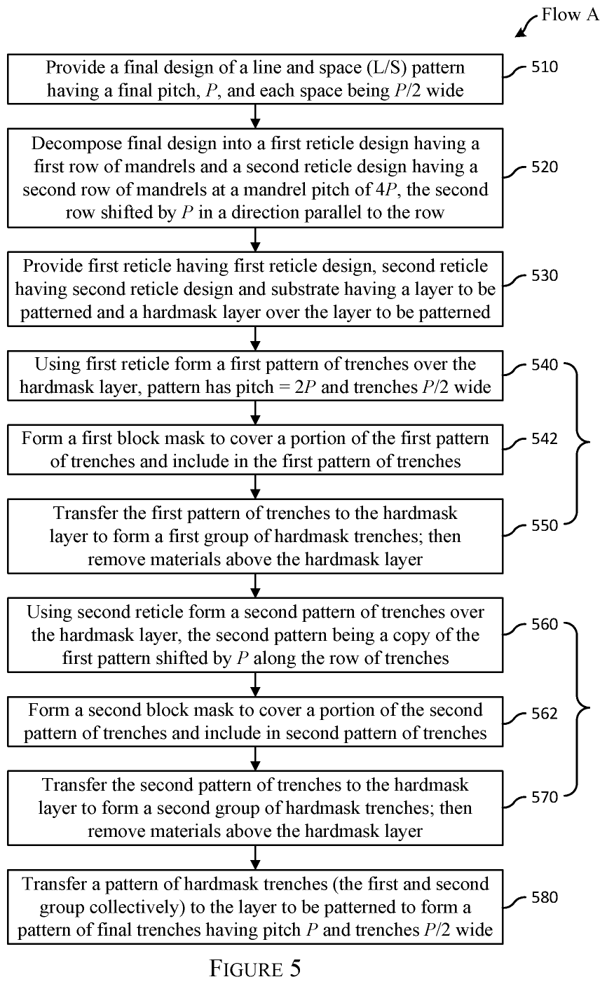

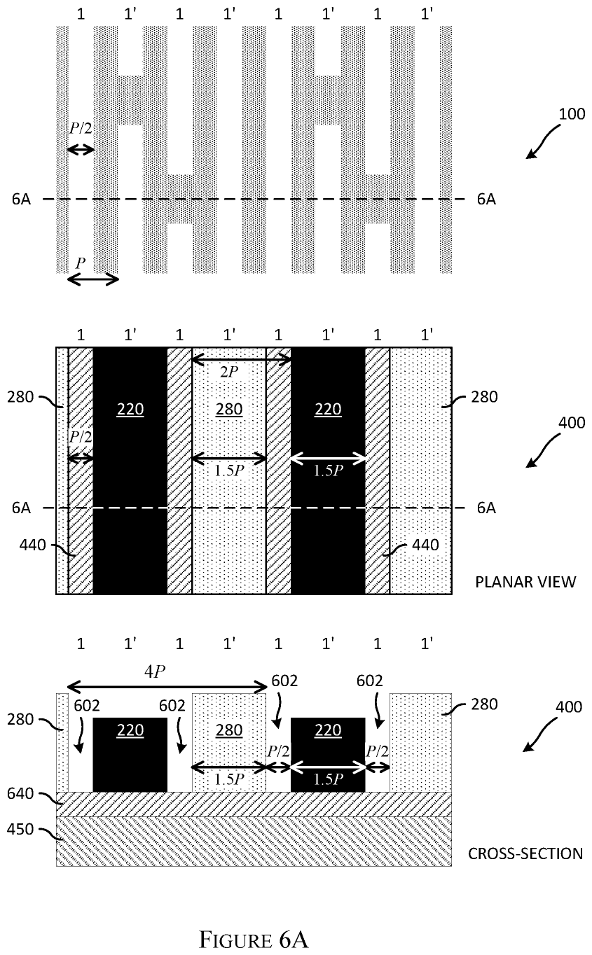

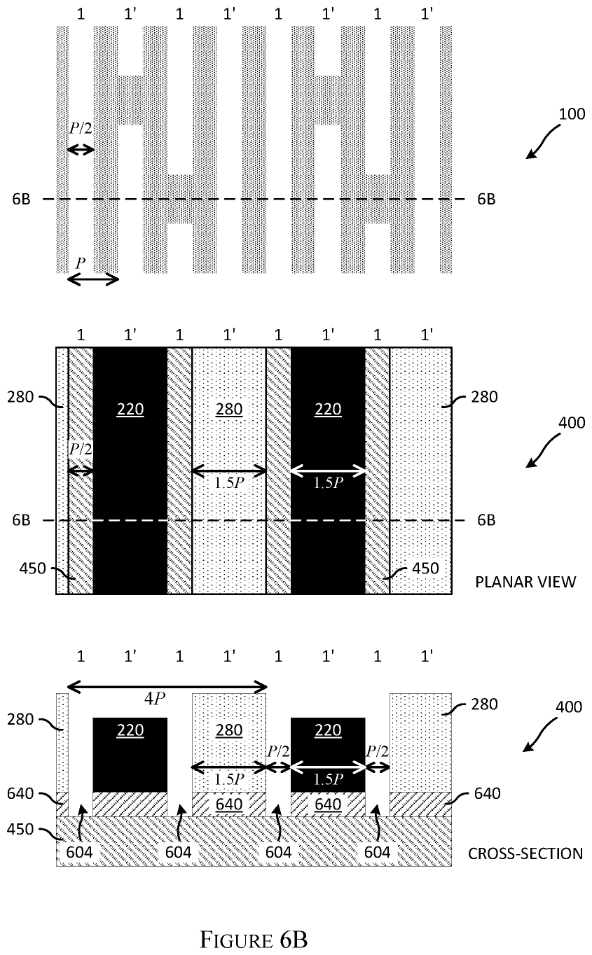

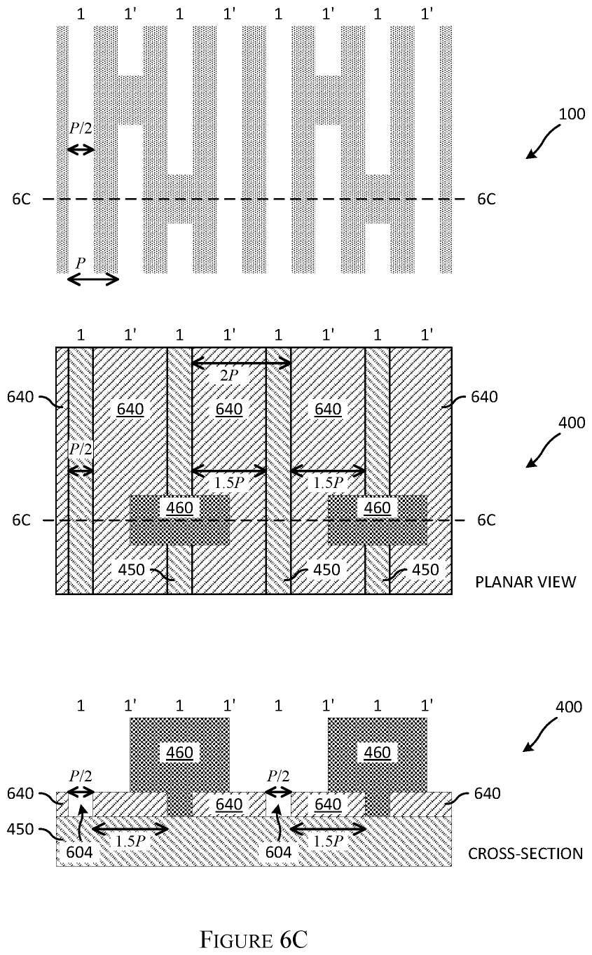

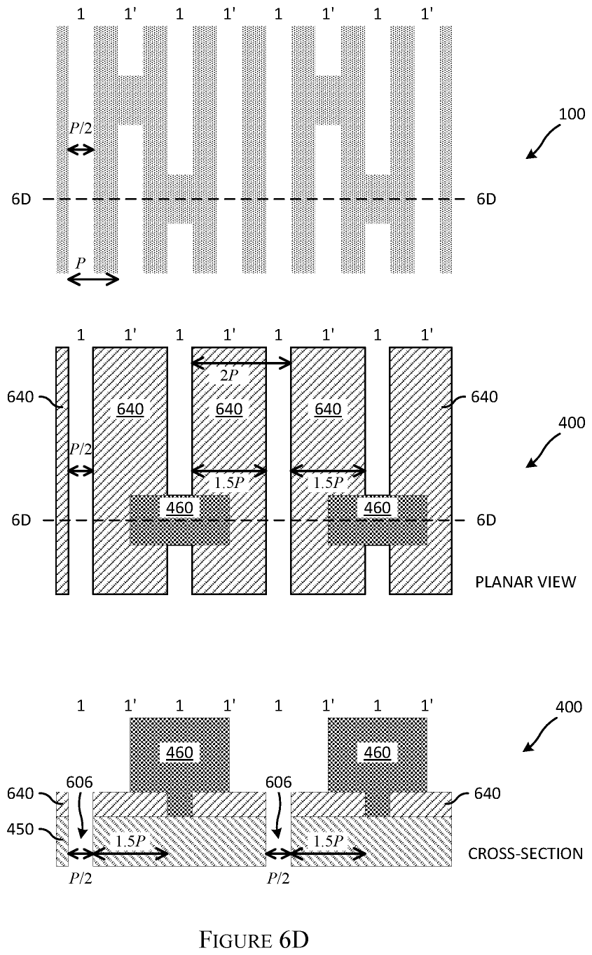

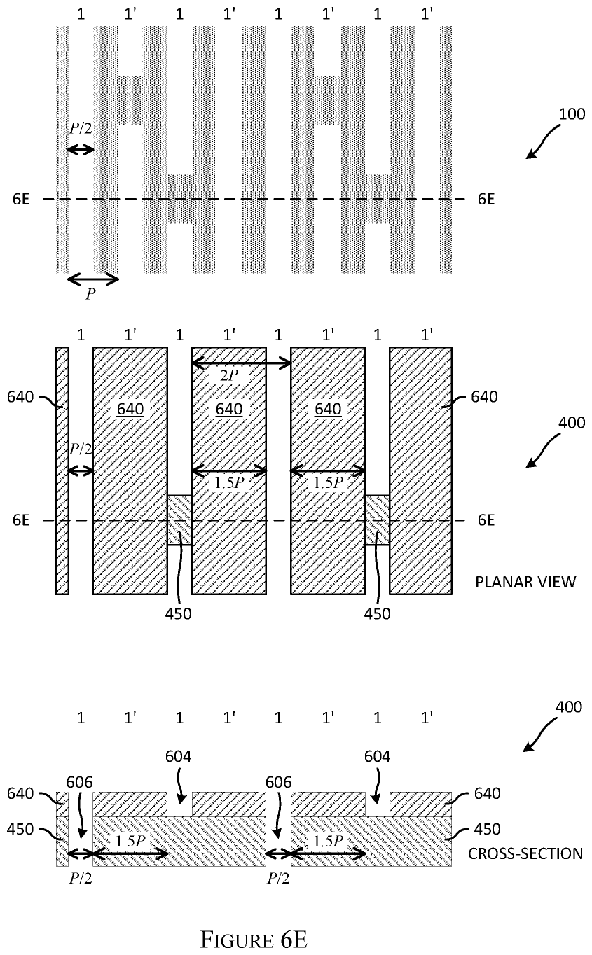

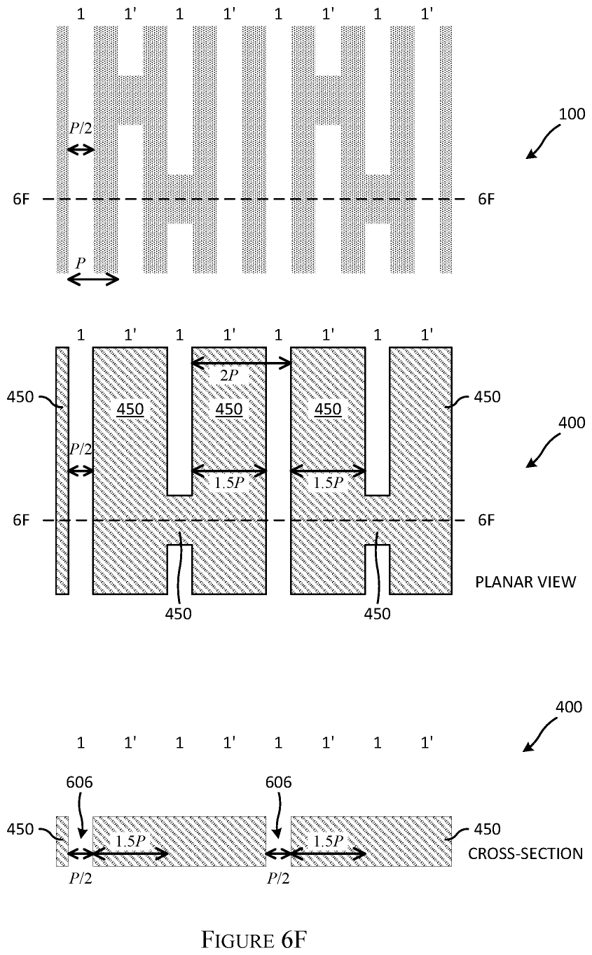

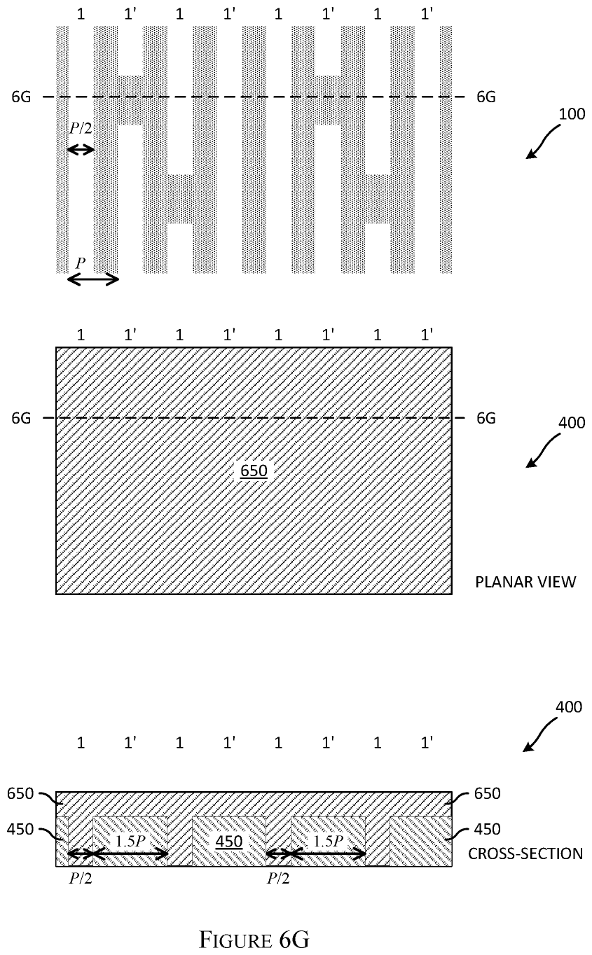

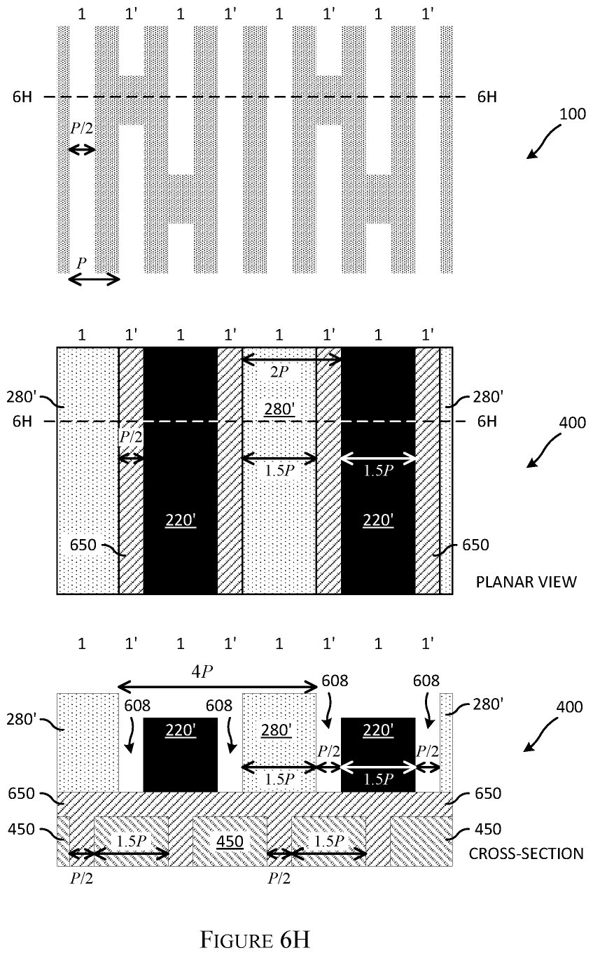

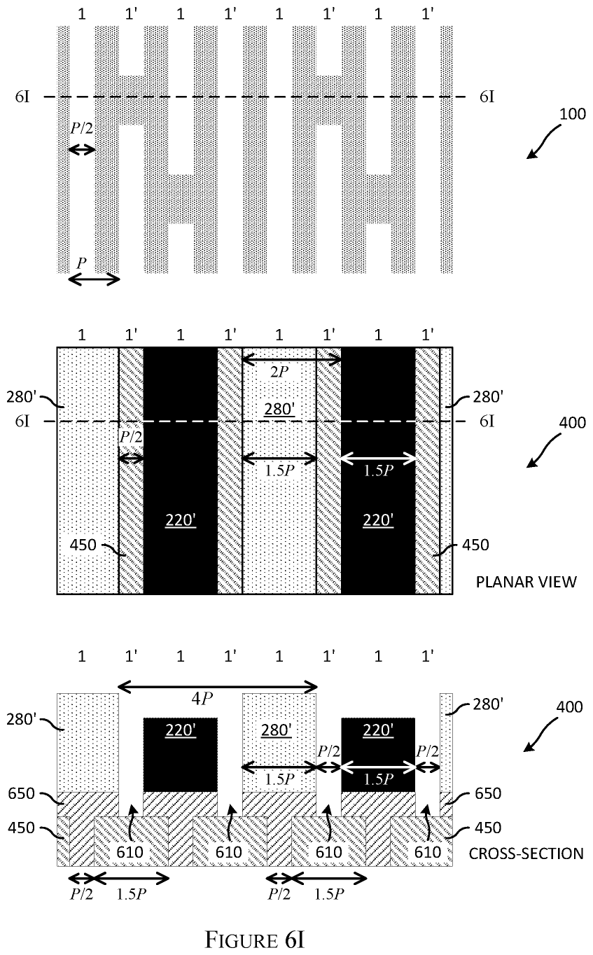

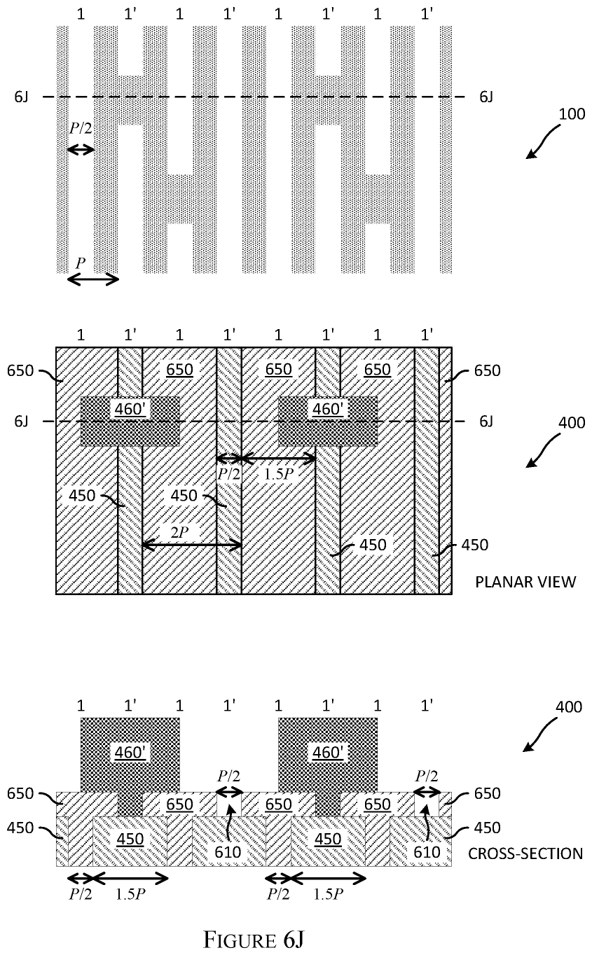

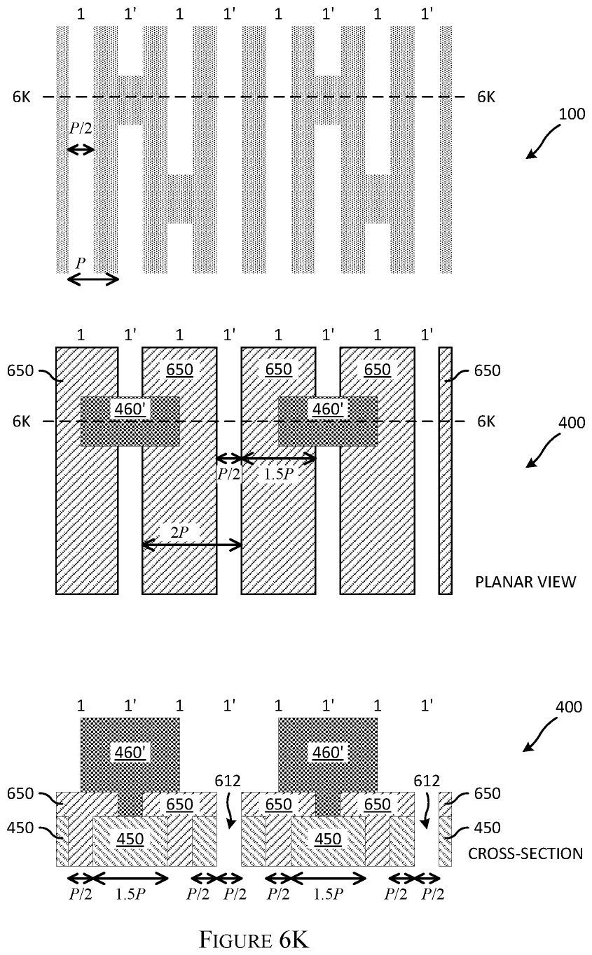

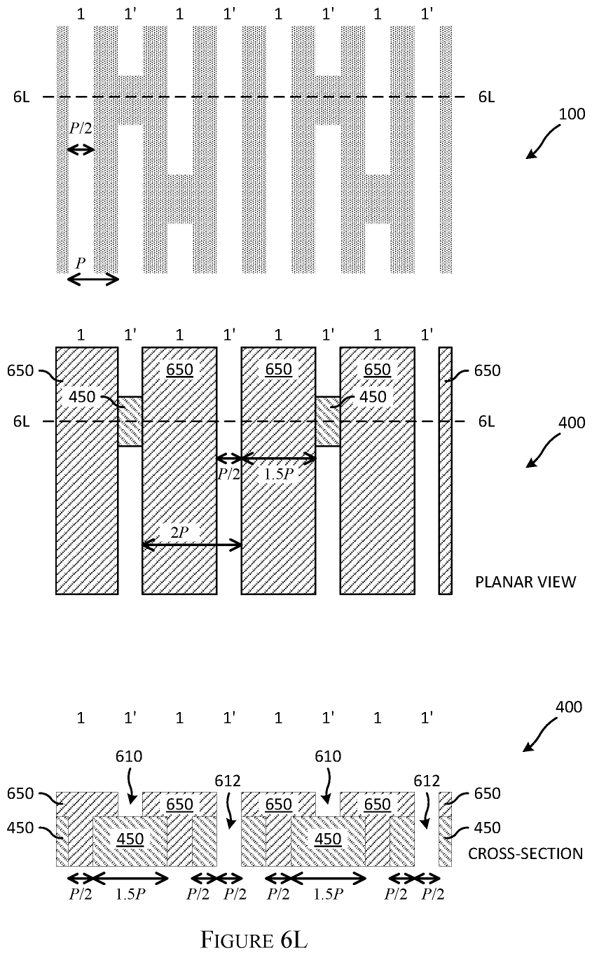

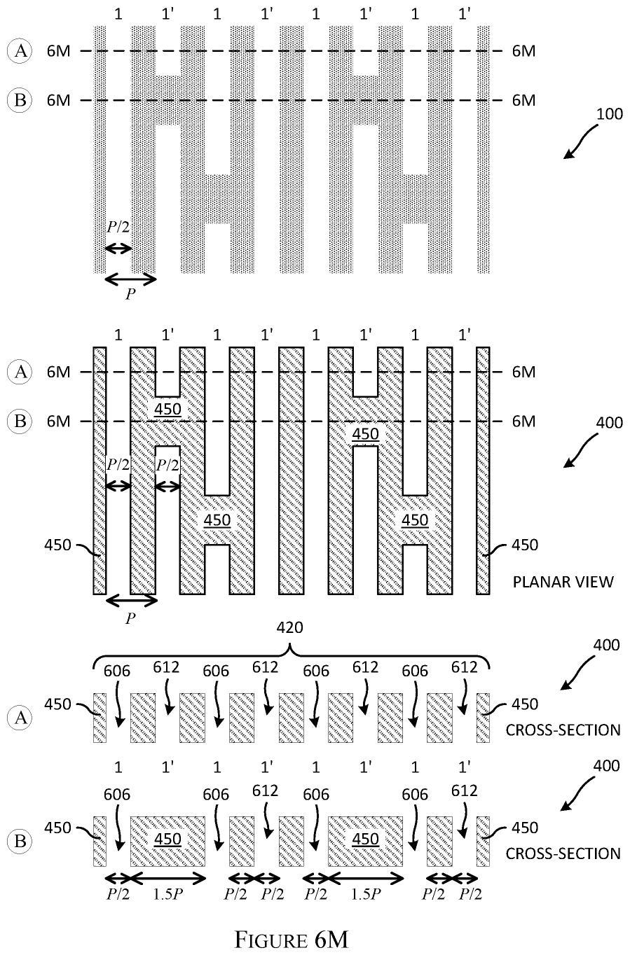

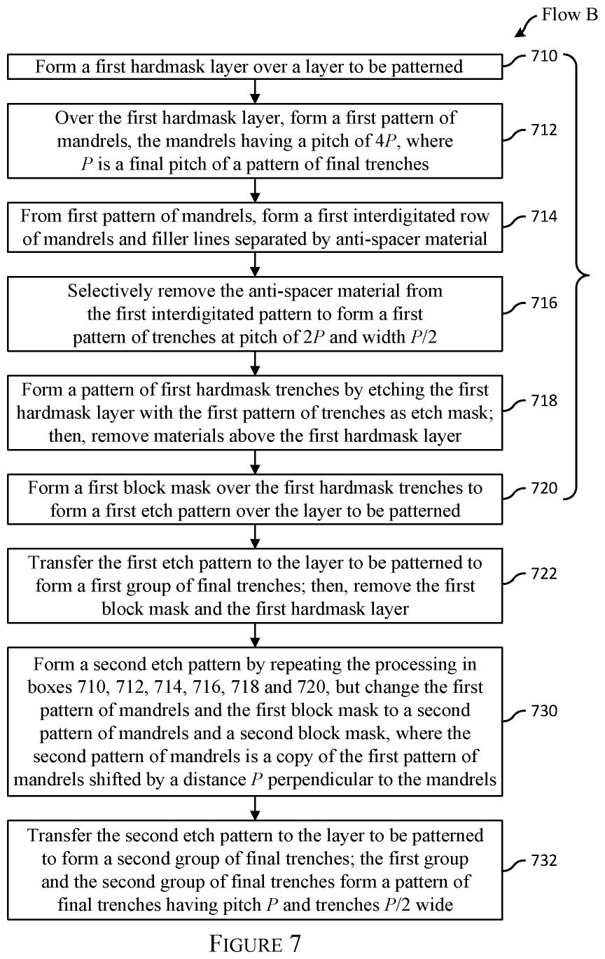

One example embodiment of a process flow, flow A, for quadruple patterning with AS-SALELE is described with reference to cross-sectional views and planar views of a semiconductor device 400 illustrated in FIGS. 4A-4I and summarized in a flowchart illustrated in FIG. 5. Another example embodiment of a process flow, flow B, for quadruple patterning with AS-SALELE is described with reference to FIGS. 6A-6M and summarized in a flowchart illustrated in FIG. 7. Both flow A and flow B use the reticle decomposition illustrated in FIGS. 1A-1F and, for the sake of specificity, the in-diffusion anti-spacer formation process to form a final pattern in a layer to be-patterned of a substrate.

FIG. 1A illustrates a final design 100 for a pattern of final trenches 102 having sides separated by lines 104 and ends separated by blocks 106. The final trenches 102 are placed at a final pitch, P, where each final trench of the pattern of final trenches 102 has a width equal to the half-pitch, P/2. In various embodiments, P may be from about 10 nm to about 30 nm. Each of the final trenches 102 has the same width. This is a limitation of the AS-SALELE technique because the final trenches 102 are not drawn features: Each final trench of the pattern of final trenches 102 has a width defined by the width of an anti-spacer, which is defined by process parameters of an anti-spacer formation process. Typically, such a limitation can be accommodated if, for example, the trenches are subsequently filled with metal to form the wires in a metal level used for carrying signals over short distances and also for locally supplying power tapped from buried power rails, in instances where the technology platform supports such an option for power distribution over long distances.

The pattern of final trenches, in the example final design 100, is a row of columnar final trenches 102, where adjacent columns along the row have been marked 1 and 1′. The markings are intended to help understand the placement and dimensions of features in a decomposition of the final pattern 100 into a set of reticles.

A design for a first mandrel reticle R1 and a design for a first block mask BLK1 are described with reference to FIGS. 1B and 1C, respectively. The features illustrated in FIGS. 1B and 1C have been drawn superposed on a background of the final design 100, shown with a light shade in FIGS. 1B and 1C. The design for the first mandrel reticle R1 and the design for first block mask BLK1 are for forming a first pattern of trenches that define a first etch pattern for etching the final trenches 102 that are located along the columns marked 1 in the final design 100. Accordingly, during processing, anti-spacer material is formed along the columns marked 1, forming anti-spacer lines 110, disposed along sides of each mandrel 120 of a first row of mandrels 120. The anti-spacer lines 110, indicated by dashed rectangles in FIG. 1B, are not features that are drawn in the first mandrel reticle R1. The drawn features in the first mandrel reticle R1 are the mandrels 120 in the first row of mandrels 120. The first row of mandrels 120 is subsequently printed in a layer formed over the substrate to be utilized in executing an anti-spacer formation process. During processing, anti-spacer material would be formed self-aligned to the mandrels 120 and, after the anti-spacer material is formed, the width of each of the mandrels 120 is 1.5P, as explained further below.

The final design 100, which is the pattern to be etched into the layer to be patterned, does not uniquely determine the width of each of the mandrels 120 in the first mandrel reticle R1. Instead, the final design 100 fixes the width of each anti-spacer line 110 to be equal to P/2 (the width of each of the final trenches 102) and the pitch for the anti-spacer lines 110 along the columns marked 1 to be equal to 2P (the pitch of the final trenches 102 along the columns marked 1). A pitch of 2P and a linewidth of P/2 means that the distance between anti-spacer lines 110 is 1.5P. Thus, as illustrated in FIG. 1B, the final design 100 requires that the width of one line of a combined mandrel and anti-spacer structure 130 be 2.5P. (The width of two anti-spacer lines 110 (each of width P/2) and a distance of 1.5P separating the two anti-spacer lines 110 add up to a combined width of 2.5P.) The space between adjacent lines of the combined mandrel and anti-spacer structure 130 is the space, 1.5P, between adjacent anti-spacer lines 110. Hence, a row of the combined mandrel and anti-spacer structures 130 has a pitch of 4P. Since each combined mandrel and anti-spacer structure 130 has one mandrel, the first mandrel reticle R1 has the first row of mandrels 120 drawn at the pitch of 4P.

Although the pitch, 4P, is independent of which anti-spacer formation process is used, the width of each of the mandrels 120 in the first mandrel reticle R1 depends on the anti-spacer formation process. In some anti-spacer formation processes (e.g., the in-diffusion anti-spacer formation process described below with reference to FIGS. 2A-2F), the width of the printed mandrel is altered by an anti-spacer formation process that converts a portion of the printed mandrel to anti-spacer material. In such cases, the width of each of the mandrels 120 in the first mandrel reticle R1 must be drawn larger than 1.5P such that, after the anti-spacers are formed, the mandrel is 1.5P wide, as defined by the final design 100. If the anti-spacer formation process leaves the mandrel width unaltered (e.g., the out-diffusion anti-spacer formation process described below with reference to FIGS. 3A-3C), each mandrel 120 is drawn 1.5P wide.

The example first mandrel reticle R1, illustrated in FIG. 1B, is suitable for use in an in-diffusion anti-spacer formation process, where each anti-spacer line is P/2 wide. The in-diffusion anti-spacer formation process converts a portion of each mandrel 120 to anti-spacer material. Hence, the mandrels 120 are drawn 2.5P wide, with the anticipation that a P/2 wide peripheral region of each of the printed mandrels would be converted to anti-spacer material, as indicated by the anti-spacer lines 110 in FIG. 1B.

The blocks 106 along the columns marked 1 may be patterned using the design for the first block mask BLK1, illustrated in FIG. 1C. The design for the first block mask BLK1 comprises block features 140 that are drawn covering the location of blocks 106 along the columns marked 1 in the final design 100. The blocks 106 being formed self-aligned to the trenches 102 in the row direction, as explained in detail further below, the extent of the block feature 140 in the row direction may be drawn to be large enough to provide sufficient margin for edge placement error (EPE), as long as the block feature 140 does not extend to come within an EPE of another final trench 102 along another column marked 1.

FIGS. 1D-1F are used to describe a design for a second mandrel reticle R2 and a design for a second block mask BLK2, which are for forming a second pattern of trenches that define a second etch pattern used for etching the final trenches 102 that are located along the columns marked 1′. The final design 100 is reproduced in FIG. 1D for convenience.

FIG. 1E illustrates a design for the second mandrel reticle R2 superposed on a background of the final design 100. Similar to the first mandrel reticle R1, the second mandrel reticle R2 comprises a second row of mandrels 120′ that is subsequently printed in a layer formed over the substrate. Also, similar to first mandrel reticle R1, the second mandrel reticle R2 is suitable for use in an in-diffusion anti-spacer formation process, where each anti-spacer line is P/2 wide. Hence, same as for mandrels 120, each mandrel 120′ is drawn 2.5P wide, anticipating that the mandrel material at the locations of anti-spacer lines 110′ would get converted to anti-spacer material. As explained above, similar to the first mandrel reticle R1, each combined mandrel and anti-spacer structure 130′ is 2.5P wide and spaced from adjacent features by 1.5P, resulting in the second row of mandrels 120′ in the second mandrel reticle R2 having the same pitch 4P, same as for the first row of mandrels 120 in the first mandrel reticle R1.

The anti-spacer lines 110′, indicated by dashed rectangles in FIG. 1E, are along the columns marked 1′, while the anti-spacer lines 110 (in FIG. 1B) are along the columns marked 1. The row of columnar final trenches 102 are arranged at a pitch P (see FIG. 1D). The columns along this row, alternate between a columns marked 1 and columns marked 1′, which means that the row of columns marked 1′ is the row of columns marked 1 displaced by a distance P along the row. Accordingly, as illustrated in FIG. 1E, the second row of mandrels 120′ is simply the first row of mandrels 120 shifted by a distance P along the row direction.

The design for the second block mask BLK2, illustrated in FIG. 1F, may be used to pattern the blocks 106 along the columns marked 1′. Similar to the design for the first block mask BLK1, the design for the second block mask BLK2 comprises block features 140′ that are drawn covering the location of blocks 106 along the columns marked 1 in the final design 100.

As mentioned above, there are two methods for forming anti-spacers described in this disclosure. In both methods the anti-spacer material is formed to separate mandrels and filler-lines in a row of interdigitated pattern of mandrels and filler-lines, where the alternating mandrels and filler-lines are arranged at a pitch of 4P. After the anti-spacer material has been formed, irrespective of the formation method, anti-spacer material of a thickness P/2 would be separating adjacent mandrels and filler-lines, where each of the mandrels and filler-lines would be having a width of 1.5P, consistent with the pitch of 4P. The pattern comprising mandrels, filler-lines, and anti-spacer material may be formed with materials that are, typically, deposited by inexpensive spin-on processing using, for example, spin-coaters in a lithography track.

The two anti-spacer formation methods are described with reference to FIGS. 2A-2F and FIGS. 3A-3C, respectively. As illustrated in FIGS. 2A-2F and FIGS. 3A-3C, the interdigitated pattern (mentioned above) is formed over a layer 240 of a substrate comprising a base layer 250 below the layer 240. In the example embodiments described in this disclosure, the layer 240 may be a hardmask layer and the base layer 250 may be a layer to be patterned.

An in-diffusion anti-spacer formation process is described first with reference to FIGS. 2A-2F.

Referring to FIG. 2A, a row of mandrels 220 having a pitch 4P is patterned over the layer 240 using, for example, the first mandrel reticle R1, described above with reference to FIGS. 1A and 1B. The mandrel material may be selected from various materials, for example, flowable materials, photoresists, and inorganic materials. In some embodiments, the mandrel material comprises a photoresist, for example, a high speed EUV photoresist. The photoresist may be patterned by exposing it to a radiation pattern defined by a reticle design, for example, the first row of mandrels 120 drawn in the first mandrel reticle R1. The radiation pattern is transferred to the exposed photoresist with a suitable developer to form the patterned mandrels 220. The pattern transfer results in each of the patterned mandrels 220 having the same width as each of the drawn mandrels 120 in the first mandrel reticle R1. Hence, the patterned width is 2.5P.

As mentioned above, the width of each of the patterned mandrels 220 formed over the layer 240 depends on the anti-spacer formation process. In the example embodiment, described with reference to FIGS. 2A-2F, the anti-spacer formation process comprises in-diffusion of a chemically active species that converts a portion of each mandrel 220 in a region near its periphery to anti-spacer material. Conversion of mandrel material to anti-spacer material shrinks the width of the patterned mandrel 220 by P and the height by P/2. Thus, prior to the conversion, in FIG. 2A, the width of each of the patterned mandrels 220 is equal to the width of the combined mandrel and anti-spacer structure 130, which is 2.5P, as explained above with reference to FIG. 1B.

In FIG. 2B, the pattern of mandrels 220 is covered with a first overcoat 260. The first overcoat 260 comprises the chemically active species. For example, the first overcoat 260 may be a photoresist comprising an acid or photo-acid, which is the chemically active species. The first overcoat 260 may be formed using a spin-on process. In various embodiments, in-diffusion of the chemically active species and reaction with the mandrels 220 are thermally activated by annealing the substrate at a controlled temperature of about 110° C. to about 220° C. for about 0.5 minute to about 3 minutes using, for example, a baking oven in a lithography track. As illustrated in FIG. 2C, the anneal temperature and anneal duration are selected to diffuse the chemically active species into the mandrels 220 and react with the mandrel material within a specific diffusion distance to convert the mandrel material there to anti-spacer material 210. The arrows pointing inward in FIG. 2C indicate a continuous region of anti-spacer material 210 of thickness P/2 formed by reaction with mandrel material in a peripheral region along the sides and tops of the mandrels 220. With the 2.5P wide printed mandrels 220 (in FIGS. 2A and 2B) shrinking to 1.5P and forming the P/2 thick anti-spacer material 210, the combined mandrel and anti-spacer structure 230 (combination of mandrel 220 and anti-spacer material 210), in FIG. 2C, is 2.5P wide.

After the annealing is completed, the first overcoat 260, comprising the chemically active species, may be removed selectively using solvents that the overcoat was cast from, as illustrated in FIG. 2D.

In FIG. 2E, a first filler material 270 has been deposited over the substrate. As illustrated in FIG. 2E, the first filler material 270 is a flowable material intended to flow into the spaces defined by the pattern of mandrels 220. In some embodiments, the first filler material 270 is a photoresist and may be deposited by inexpensive spin-on processing. Typically, the first filler material 270 would overfill the spaces defined by the pattern of mandrels 220, covering the surface of the anti-spacer material 210 with a topcoat of excess first filler material 270. Hence, a controlled recess etch step may be performed to remove the topcoat and expose the anti-spacer material 210 formed over the mandrels 220. The controlled recess etch step may be using a solvent in which the exposed materials have a low dissolution rate. In some embodiments, the solvent may be 0.26N tetramethyl ammonium hydroxide (TMAH) developer. Exposing the top surface of the anti-spacer material 210 forms filler-lines 280 separated by anti-spacer material 210 in a row of alternating mandrels 220 and filler-lines 280.

As mentioned above, two examples methods for forming anti-spacers are described in this disclosure. The in-diffusion anti-spacer formation process has been described above with reference to FIGS. 2A-2F. The out-diffusion anti-spacer formation process is described below with reference to FIGS. 3A-3C. In the out-diffusion process, the mandrels supply the chemically active species that diffuses into an adjacent material and chemically react to convert the adjacent material within a controlled diffusion distance to anti-spacer material. None of the mandrel material gets chemically converted to anti-spacer material.

FIG. 3A illustrates a cross-sectional view of a semiconductor device where, similar to the row of mandrels 220 in FIG. 2A, a row of mandrels 320 having a pitch of 4P is patterned over the layer 240 using the first mandrel reticle R1, except, in this example, each of the mandrels 120 has been drawn to have a width equal to 1.5P, instead of 2.5P. The mandrels 220 had to be patterned wider (at a width of 2.5P) in the in-diffusion process because a portion of the mandrel material was converted to anti-spacer material 110 by reaction with the chemically active species, as explained above. In the out-diffusion process, the mandrel width in the row of mandrels 320 remain unaltered at 1.5P. Similar to the in-diffusion process, in the out-diffusion process, the row of mandrels 320 may be patterned using a suitable lithography technique (e.g., EUV lithography).

In the out-diffusion process, the mandrels in the row of mandrels 320 supply the chemically active species. Thus, the mandrel material in FIG. 3A may be a photoresist comprising an acid or photo-acid, which is the chemically active species.

In FIG. 3B, a second filler material 370 has been deposited over the patterned row of mandrels 320. The second filler material 370 is a flowable material, intended to flow into the vacant spaces defined by the pattern of the row of mandrels 320. If reacted with the chemically active species present in the patterned row of mandrels 320, the second filler material 370 would get converted to anti-spacer material. In some embodiments, the second filler material 370 is a photoresist and may be deposited by spin-on processing. In the example embodiment in FIG. 3B, similar to the first filler material 270, the second filler material 370 overfills the spaces between mandrels 320, the excess material forming a topcoat.

In FIG. 3C, the substrate has been annealed to diffuse the chemically active species from the row of mandrels 320 into the second filler material 370. The anneal process may be similar to the annealing in the in-diffusion process, described with reference to FIGS. 2B and 2C. During annealing, the out-diffusing chemically active species reacts with a portion of the second filler material 370 that is adjacent to each of the mandrels in the row of mandrels 320. The reaction converts a region within a diffusion distance into the second filler material 370 to the anti-spacer material 310. As described above, the temperature and duration of the annealing are selected and controlled for the diffusion distance to be equal to P/2. In some embodiments, the topcoat of the second filler material 370 seen in FIG. 3B may be completely converted to anti-spacer material 310, thereby exposing the anti-spacer material 310 formed over the mandrels 320 to form filler-lines 380 separated by anti-spacer material 310 in a row of alternating mandrels 320 and filler-lines 380. In some other embodiments, there may be a residual topcoat, which may be removed by an extended development step in which the solvent used to remove the residual topcoat slowly and controllably recesses the residual topcoat because of its minimal dissolution rate, thereby revealing the anti-spacer material. Removing the topcoat exposes the anti-spacer material 310 formed over the mandrels 320 and forms filler-lines 380 separated by anti-spacer material 310 in a row of alternating mandrels 320 and filler-lines 380, as illustrated in FIG. 3C.

It is noted that, in the in-diffusion process, the first filler material 270, used to form the filler-lines 280 is deposited after the anti-spacer material 210 has been formed. In contrast, in the out-diffusion process, the first filler material 370, used to form the filler-lines 380 in the row of alternating mandrels 320 and filler-lines 380 separated by anti-spacer material 310, is deposited before the anti-spacer material 310 has been formed.

Initially, the material reacting with the chemically active species has a low solubility in a solvent prior to the chemical reaction. The chemistry used in the anti-spacer formation processes is such that the reaction with the chemically active species alters the material to anti-spacer material (material that has a high solubility in the solvent). Thus, after the chemically active species has diffused and reacted to convert the material within the diffusion distance to anti-spacer material, the anti-spacer material may be selectively removed by the solvent. In some embodiments, where the chemically active species is an acid or photo-acid diffusing into and reacting with a photoresist, the solvent with which the anti-spacer material may be removed selectively comprises tetramethylammonium hydroxide (TMAH).

The row of interdigitated pattern of mandrels 220 and filler-lines 280, separated by anti-spacer material 210 (illustrated in FIG. 2F), and the row of interdigitated pattern of mandrels 320 and filler-lines 380, separated by anti-spacer material 310 (illustrated in FIG. 3C), have the same lateral dimensions. Thus, either anti-spacer formation process may be utilized to form the interdigitated patterns needed in process flows for quadruple patterning with AS-SALELE.

Flow A is described with reference to cross-sectional views and planar views of a semiconductor device 400 illustrated in FIGS. 4A-4I and the flowchart in FIG. 5.

As mentioned above, the example embodiments of process flows (flow A and flow B) for implementing the final design 100 (illustrated in FIG. 1A) with AS-SALELE quadruple patterning use a reticle set that is designed to be consistent with the in-diffusion anti-spacer formation process (illustrated in FIGS. 2A-2F), for the sake of specificity. Thus, the reticle set selected for flow A and flow B has the following four reticles: the first mandrel reticle R1, the reticle with the design for the first block mask BLK1, the second mandrel reticle R2, and the reticle with the design for the second block mask BLK2 (illustrated in FIGS. 1A-1F). Accordingly, an initial state of the substrate, for flow A (and flow B), is the patterned structure illustrated in the cross-sectional view in FIG. 2F, formed using the first mandrel reticle R1 and is referred to here as the first interdigitated pattern. In flow A, the layer 240 (in FIG. 2F) is a hardmask layer and the base layer 250 (in FIG. 2F) is the layer to be patterned. For clarity, the labels, layer 240 and the base layer 250 in FIG. 2F, are changed in FIGS. 4A-4I to hardmask layer 440 and the layer to be patterned 450, respectively.

FIG. 4A shows cross-sectional and planar views of a semiconductor device 400 after the anti-spacer material 210 formed by the in-diffusion anti-spacer formation process (e.g., a first anti-spacer formation process) has been removed selectively from the first interdigitated pattern using a first anti-spacer material removal process. As mentioned above, the anti-spacer material 210 may be selectively removed by a solvent, such as TMAH.

Referring to FIG. 4A, first structures, which include a first row of lines that are parallel with each other and spaced apart from each other, are formed over a memorization layer. The first structures (e.g., mandrels 220) in FIG. 4A and the filler-lines 280 (e.g., a first fill material) are formed over a memorization layer (e.g., hardmask layer 440). The first structures may be formed of photoresist. In some embodiments, the hardmask layer 440 may comprise silicon nitride, and the layer to be patterned 450 may comprise silicon oxide. In some other embodiments, the hardmask layer 440 may comprise silicon carbide, titanium nitride, tantalum nitride, or the like, or a combination of thereof, and the layer to be patterned 450 may comprise a low-k dielectric such as carbon-doped oxide, fluorosilicate glass, porous oxide, and the like.

The selective removal of anti-spacer material 210 creates a first pattern of trenches 402 (e.g. first trenches formed along sidewalls of the first structures and sidewalls of a first fill material), as illustrated in FIG. 4A. Each trench of the first pattern of trenches 402 has a width of P/2 and, with the trenches being along columns marked 1, the pitch for the first pattern of trenches 402 is 2P. In some embodiments, the trench opening P/2 may be a critical dimension that limits the packing density in, for example, a static random access memory (SRAM) cell embedded in a digital logic IC. By using the thickness of the anti-spacer material to define the width of each trench of the first pattern of trenches 402, the critical dimension is defined by the diffusion distance. Since the diffusion distance is controlled by anneal temperature and anneal duration instead of lithography, critical dimensions of a few nanometers may be manufacturable, and a controlled trench width as narrow as 4 nm may be achieved.

In FIG. 4B, the reticle with the design for the first block mask BLK1, described with reference to FIG. 1C, is used to pattern a first block mask 460 over the first pattern of trenches 402. In some embodiments, the first block mask 460 may comprise spin-on-glass or titanium nitride and may be formed by etching selective to the mandrels 220, the filler-lines 280, and the hardmask 440 using a standard etch chemistry for pattering transfer, as known to persons skilled in the art. As illustrated in FIG. 4B, the features of the first block mask 460 cover a portion of the first pattern of trenches 402, illustrated in FIG. 4A, thereby forming an etch pattern comprising the first pattern of trenches 402, illustrated in FIG. 4B, that includes the first block mask 460, in addition to the mandrels 220 and the filler-lines 280. In this disclosure, the trenches of the first pattern of trenches 402 may be referred to as first stencil trenches since they form an etch pattern (e.g., a first etch pattern) for a patter transfer etch performed subsequently.

In FIG. 4C, a pattern transfer etch has been performed to transfer the first pattern of trenches 402 (shown in FIG. 4A) to the hardmask layer 440 to form a first group of hardmask trenches 404. The pattern transfer etch may be using, for example, anisotropic reactive ion etching (RIE) with a suitable etch chemistry, for example, a fluorine chemistry, that etches hardmask 440 and stops on the layer to be patterned 450, as illustrated in FIG. 4C.

After the first group of hardmask trenches 404 has been formed, the mandrels 220, the filler-lines 280, and the first block mask 460 are stripped off the substrate. The resulting structure of the semiconductor device 400 is illustrated in FIG. 4D. As illustrated in FIG. 4D, the first group of hardmask trenches 404 exposes a portion of the layer to be patterned along the columns marked 1. In this example (flow A), the pattern of the first group of hardmask trenches 404 is not transferred to the layer to be patterned 450 at this juncture. Prior to that, a second group of hardmask trenches is formed to expose another portion of the layer to be patterned 450, this portion being along the columns marked 1′. In flow A, the layer to be patterned 450 may be etched after exposing the portion along columns marked 1′.

The method for forming the second group of hardmask trenches, is similar to the method for forming the first group of hardmask trenches 404. After forming the first group of hardmask trenches 404, the in-diffusion anti-spacer formation process flow (described above with reference to FIGS. 2A-2F) may be executed to form a second interdigitated pattern over the hardmask 440 using the second mandrel reticle R2. It is noted that the in-diffusion anti-spacer formation process has been selected for the sake of specificity only. It may be replaced by the out-diffusion anti-spacer formation process (described above with reference to FIGS. 3A-3C) with appropriate materials and reticle to form the same second interdigitated pattern.

The second interdigitated pattern (formed using the second mandrel reticle R2) is same as the first interdigitated pattern (formed using the first mandrel reticle R1), except the anti-spacer lines in the second interdigitated pattern are along columns marked 1′, instead of being along columns marked 1. In other words, shifting the first interdigitated pattern by a distance P along the row produces the second interdigitated pattern. The second mandrel reticle R2 is also designed for use with an in-diffusion anti-spacer formation process, same as the first mandrel reticle R1, to form the second interdigitated pattern, i.e., the width of mandrels 120 in the first mandrel reticle R1 (in FIG. 1B) and the width of mandrels 120′ in the second mandrel reticle R2 (in FIG. 1E) are 2.5P and, likewise, the pitch for the first row of mandrels (in the first mandrel reticle R1) and the pitch for the second row of mandrels (in the second mandrel reticle R2) are 4P.

The materials and processing to form the second interdigitated pattern may be similar to those described above for forming the first interdigitated pattern.

After forming the second interdigitated pattern, the anti-spacer material formed by the in-diffusion anti-spacer formation process (e.g., a second anti-spacer formation process) is removed from the second interdigitated pattern (i.e., a second anti-spacer material removal process). FIG. 4E illustrates the structure of the semiconductor device 400 after the anti-spacer material has been removed selectively by a solvent, such as TMAH.

Referring to FIG. 4E, second structures, which include a second row of lines that are parallel with each other and spaced apart from each other, are formed over the memorization layer. Removing the anti-spacer material results in a row of alternating mandrels 220′ (e.g., second structures) and filler-lines 280′ (e.g., a second fill material) separated by a second pattern of trenches 406 being formed over the hardmask layer 440 (e.g., the memorization layer). The second pattern of trenches 406 (e.g., second trenches formed along sidewalls of the first structures and sidewalls of a first fill material), in FIG. 4E, may be the same as the first pattern of trenches 402 (in FIG. 4A), but shifted relative to the first pattern of trenches 402 by a distance P in a direction parallel to the row. Because of the shift along the row by P, the first group of hardmask trenches 404 in FIGS. 4C and 4D are now covered by the mandrels 220′ and filler lines 280′, which are 1.5P wide, as illustrated in FIG. 4E.

In FIG. 4F, the design for the second block mask BLK2, described with reference to FIG. 1F, is used to pattern a second block mask 460′ over the second pattern of trenches 406. As illustrated in FIG. 4F, the features of the first block mask 460′ covers a portion of the second pattern of trenches 406, as seen in FIG. 4E, thereby forming an etch pattern comprising the second pattern of trenches 406, as seen in FIG. 4F, where a definition of the second pattern of trenches 406 includes the second block mask 460′, in addition to the mandrels 220′ and the filler-lines 280′. In this disclosure, the trenches of the second pattern of trenches 406 may be referred to as second stencil trenches since they form an etch pattern (e.g., a second etch pattern) for a pattern transfer etch performed subsequently.

The materials and processing used to form the second block mask 460′ may be similar to those used to form the first block mask 460.

In FIG. 4G, a pattern transfer etch has been performed to transfer the second pattern of trenches 406 (shown in FIG. 4E) to the hardmask layer 440 to form a second group of hardmask trenches 408. The etch process may be similar to that used to form the first group of hardmask trenches 404.

In FIG. 4H, materials above the hardmask layer 440, which include the mandrels 220′, the filler lines 280′ and the second block mask 460′, have been removed after forming the second group of hardmask trenches 408. The second group of hardmask trenches 408 and the first group of hardmask trenches 404 collectively form a pattern of hardmask trenches 410 having the final pitch, P, as illustrated in FIG. 4H. The pattern of hardmask trenches 410 matches the final design 100, as seen from a comparison of the planar view of the semiconductor device 400 with the final design 100 in FIG. 4I. Hence the pattern of hardmask trenches 410 may be used as an etch mask to pattern the layer to be patterned 450 with a pattern replicating the final design 100.

FIG. 4I illustrates the semiconductor device 400 after the layer to be patterned 450 has been etched using the pattern of hardmask trenches 410 (illustrated in FIG. 4H) as the etch mask, and the hardmask 440 has been removed. The etching transfers the pattern of hardmask trenches 410 to the layer to be patterned 450 to form a pattern of final trenches 420. The pattern of final trenches 420 comprises a row of columnar trenches having the final pitch, P, where each trench of the pattern of final trenches 420 has a width of P/2. As seen from a comparison of the planar view of the semiconductor device 400 with the final design 100 in FIG. 4I, the final design 100 has been replicated by the pattern of final trenches 420 in the layer to be patterned 450. Two cross-sectional views are shown in FIG. 4I. One cross-sectional view, marked A, is in a plane where features of the block mask 460′ were absent during processing, while the second cross-sectional view, marked B, illustrates two blocked trenches in the pattern of final trenches 420.

A summary of process flow A for quadruple patterning with AS-SALELE, described above with reference to FIGS. 4A-4I, is summarized in a flowchart illustrated in FIG. 5.

As indicated in box 510, a final design is provided for patterning into a layer to be patterned. The final design comprises final trenches that are at a width of half a final pitch (P/2) and arranged in a L/S pattern at the final pitch, P.

In box 520, the final design is decomposed into a first and a second reticle designs, each design comprising a row of mandrels at a pitch of 2P, where the rows are identical except for a shift of P along the row.

The flow A provides a first mandrel reticle with the first reticle design and a second mandrel reticle with the second reticle design along with a substrate having the layer to be patterned and a hardmask layer formed over the layer to be patterned, as shown in box 530.

In boxes 540 and 542, a first pattern of trenches is formed using the first mandrel reticle and a first block mask. In flow A, prior to transferring the first pattern of trenches to the hardmask layer, the first block mask is formed and included in the first pattern of trenches.

It is noted that, as described in further detail below, flow B departs from flow A by transferring the first pattern of trenches to the hardmask layer before forming the first block mask.

In box 550, the first pattern of trenches is transferred to the hardmask layer to form a first group of hardmask trenches. As described above, the first pattern of trenches are spaces formed by selectively etching away anti-spacer material from a row of alternating mandrels and filler lines separated by anti-spacer material. As indicated in box 550, after forming the first group of hardmask trenches, materials above the hardmask layer are removed.

The processing in boxes 540, 542, and 550, used to form the first group of hardmask trenches is repeated in the processing in boxes 560, 562, and 570, except, this time, a second mandrel reticle and a second block mask are used to form a second group of hardmask trenches. Thus, the second group of hardmask trenches are formed in columns that are shifted by P along the row direction relative to the columns in which the first group of hardmask trenches are formed.

It is noted that, in flow A, the first group and the second group of hardmask trenches are formed in the same hardmask layer. In contrast, as described in further detail below, flow B forms a pattern of first hardmask trenches in a first hardmask layer, and a pattern of second hardmask trenches in a second hardmask layer.

As indicated in box 580, the first group of hardmask trenches and the second group of hardmask trenches collectively form a pattern of hardmask trenches that is transferred to the layer to be patterned. As noted in box 580, the pattern transfer etch forms a pattern of final trenches that replicates the final design, where the trenches have a width of P/2 and pitch P.

Another example embodiment of a process flow, flow B, for quadruple patterning with AS-SALELE is described with reference to FIGS. 6A-6M and summarized in a flowchart illustrated in FIG. 7. It is understood that persons skilled in the art may construct other process flows, in addition to flow A and flow B, using the inventive aspects of the embodiments of quadruple patterning with AS-SALELE described in this disclosure.

Flow B replicates the final design 100 (illustrated in FIG. 1A) in the layer to be patterned 450 of the semiconductor device 400 using the same reticle set that is used in flow A to replicate the final design 100 in the layer to be patterned 450, viz., the first mandrel reticle R1, the reticle with the design for the first block mask BLK1, the second mandrel reticle R2, and the reticle with the design for the second block mask BLK2 (described above with reference to FIGS. 1A-1F). As mentioned above, the first mandrel reticle R1 and the second mandrel reticle R2 have been designed to be consistent with the in-diffusion anti-spacer formation process (illustrated in FIGS. 2A-2F). The in-diffusion anti-spacer formation process is selected only for the sake of specificity. Thus, the first interdigitated pattern (illustrated in FIG. 2F) has been formed in flow B using the first mandrel reticle R1 and the reticle design for the first block mask BLK1.

Same as in flow A, after forming the first interdigitated pattern, the anti-spacer material 210 is removed selectively to form the same structure for the semiconductor device 400, as illustrated in FIG. 6A (reproduced from FIG. 4A). The structure illustrated in FIG. 4A being identical to the structure illustrated in FIG. 6A, the same numerals are used for the row of mandrels 220, the filler lines 280, and the layer to be patterned 450. However, the hardmask layer 440 in FIG. 4A is changed to the first hardmask layer 640 in FIG. 6A. The change from 440 to 640 is made because, unlike in flow A, in flow B, the first hardmask layer 640 is removed in a subsequent step, and a second hardmask layer is formed over the layer to be patterned 450. Also, the first pattern of trenches 402 in FIG. 4A is referred to as the first pattern of trenches 602 in FIG. 6A. The change from 402 to 602 is made because, in flow A, the first block mask 460 is included in defining the etch pattern of the first pattern of trenches 402 that is subsequently transferred to the hardmask layer 440, whereas, in flow B, the first pattern of trenches 602 that is transferred to the first hardmask layer 640 to form a pattern of first hardmask trenches 604 does not include the first block mask 460.

In FIG. 6B, a pattern transfer etch has been performed prior to transfer the unmodified first pattern of trenches 602 to the first hardmask layer 640. The etch process removes an exposed portion of the first hardmask layer 640 to form the pattern of first hardmask trenches 604. The structure of the semiconductor device 400 after pattern transfer etch is completed, illustrated in FIG. 6B, shows the pattern of first hardmask trenches 604 has trenches that expose a portion of the layer to be patterned 450 along the columns marked 1 without any blocks.

In FIG. 6C, the row of mandrels 220 and filler lines 280 (seen in FIG. 6B) has been removed, and the first block mask 460 has been formed using the reticle with the design for the first block mask BLK1. The first block mask 460 covers a portion of the first hardmask trenches 604. The pattern of first hardmask trenches 604 with a portion covered by the first block mask 460 forms a first etch pattern over the layer to be patterned 450, as illustrated in FIG. 6C.

FIG. 6D illustrates the structure of the semiconductor device 400 after the first etch pattern has been transferred to the layer to be patterned 450 to form a first group of final trenches 606. The respective pattern-transfer etch is a selective etch that is blocked in regions covered by the first block mask 460 or the first hardmask layer 640, while removing an exposed portion of the layer to be patterned 450.

After forming the first group of final trenches 606, the first block mask 460 and the first hardmask layer 640 are removed successively from the substrate, as illustrated in FIGS. 6E and 6F. FIG. 6E illustrates the structure of the semiconductor device 400 after removing the first block mask 460, and FIG. 6F illustrates the structure of the semiconductor device 400 after removing the first hardmask layer 640.

As described above and seen in FIGS. 6B-6E, the patterned first hardmask layer 640 covers the layer to be patterned 450 in the region between adjacent columns marked 1. Hence, this covered region is protected from being removed by the pattern transfer etch performed through the first etch pattern (described above with reference to FIGS. 6C-6D). When formed, the pattern of first hardmask trenches 604 exposes the layer to be patterned 450 unblocked along the entire length of each of the columns marked 1 (see FIG. 6B). However, the first block mask 460, when formed over the pattern of first hardmask trenches 604, fills a portion of the pattern of first hardmask trenches 604 (see FIG. 6C). The filling protects the portion of the layer to be patterned 450 disposed adjacent below from being removed (see FIG. 6D). Accordingly, as seen in the planar view in FIG. 6E, the trenches in the first group of final trenches 606, which are running along the columns marked 1, are blocked by the unremoved portion of the layer to be patterned 450 that has been protected from etchants by the first block mask 460 filling the respective portions of the trenches in the pattern of first hardmask trenches 604. Since the first block mask 460 has been removed in FIG. 6E, a portion of the pattern of first hardmask trenches 604 that is now unfilled is visible in the cross-sectional view of the semiconductor device 400 in FIG. 6E.

In FIG. 6F, the first hardmask layer 640 is removed after removing the first block mask 460. The planar view of the semiconductor device 400 in FIG. 6F shows that the pattern of the first group of final trenches 606 replicates the portion of the final design 100 along the columns marked 1 in the layer to be patterned 450. As illustrated in FIG. 6F, each trench of the first group of final trenches 606 has the final width P/2, and the pattern comprising the first group of final trenches 606 has a pitch 2P. Since the region between adjacent columns marked 1 includes the columns marked 1′, the portion of the final design 100 along the columns marked 1′ are yet to be replicated in the layer to be patterned 450.

FIG. 6G shows a second hardmask layer 650 formed over the layer to be patterned 450. The second hardmask layer 650 filling the first group of final trenches 606 along the columns marked 1 may be formed using processes and materials similar to those used to form the hardmask layer 440 described with reference to FIG. 4A (which is similar to the first hardmask layer 640).

After forming the second hardmask layer 650, a second group of final trenches 612 may be formed along the columns marked 1′ by repeating the steps described above with reference to FIGS. 6A-6F, but with the first mandrel reticle R1 replaced by the second mandrel reticle R2, and the reticle with the design for the first block mask BLK1 replaced by the reticle with the design for the second block mask BLK2. By using these reticles, the pattern of the second group of final trenches 612 replicates the portion of the final design 100 along the columns marked 1′ in the layer to be patterned 450. FIGS. 6H-6M illustrate planar views and cross-sectional views of the semiconductor device 400 at various intermediate stages of forming the second group of final trenches 612. The structure of the semiconductor device 400 after the processes for forming the second group of final trenches 612 are complete and the second hardmask layer 650 has been removed is illustrated in FIG. 6M.

FIG. 6H shows a second pattern of trenches 608 (similar to the first pattern of trenches 602 in FIG. 6A) formed by removing anti-spacer material from a second interdigitated pattern formed over the second hardmask layer 650 using the second mandrel reticle R2. As explained above, the second interdigitated pattern is the first interdigitated pattern shifted by a distance P in a direction perpendicular to the mandrels of the row of mandrels 220′. This positions the trenches of the second pattern of trenches 608 along the columns marked 1′.

In FIG. 6I (similar to FIG. 6B) a pattern of second hardmask trenches 610 are etched into the second hardmask layer 650 along the columns marked 1′ through the second pattern of trenches 608.

In FIG. 6J (similar to FIG. 6C), the row of mandrels 220′ and filler lines 280′ (seen in FIG. 6I) are removed and a second block mask 460′ is formed using the reticle with the design for the second block mask BLK2. The second block mask 460′ covers a portion of the second hardmask trenches 610, thus, forming a second etch pattern over the layer to be patterned 450.

In FIG. 6K, the second group of final trenches 612 is formed in the layer to be patterned 450 by performing a pattern transfer etch through the second etch pattern.

After forming the second group of final trenches 612, the second block mask 460′ and the second hardmask layer 650 are removed successively from the substrate, as illustrated in FIGS. 6L and 6M, respectively, similar to the processing done after forming the first group of final trenches 606 (see FIGS. 6E and 6F). It is noted that the first group of final trenches 606 and the second group of final trenches 612, formed using flow B, collectively form the same pattern as the pattern of final trenches 420 (illustrated in FIG. 4I), formed using flow A. Thus, the final design 100 may be replicated in the layer to be patterned 450 using either flow A or flow B.

The structure of the semiconductor device 400 after removing the second hardmask layer 650 is illustrated in FIG. 6M. The pattern of final trenches 420 (the combined first group of final trenches 606 and the second group of final trenches 612) comprises a row of columnar trenches having the final pitch, P, where each trench of the pattern of final trenches 420 has a width of P/2. As expected, the two cross-sectional views of the structure of the semiconductor device 400 in FIG. 6M are same as the respective two cross-sectional views of the structure of the semiconductor device 400 in FIG. 4I.

A summary of process flow B for quadruple patterning with AS-SALELE, described above with reference to FIGS. 6A-6M, is summarized in a flowchart illustrated in FIG. 7.

As indicated in box 710, a first hardmask layer is formed over a layer to be patterned of a substrate.

In box 712, a first pattern of mandrels is formed over the first hardmask layer. The mandrels are arranged in a row at a pitch of 4P, where P is a final pitch and P/2 is a final width of a pattern of final trenches.

In box 714, a first interdigitated pattern of a row of alternating mandrels and filler-lines separated by anti-spacer material are formed from the first pattern of mandrels. The anti-spacer material is formed self-aligned to the mandrels using an anti-spacer formation process.

As indicated in box 716, the anti-spacer material is selectively removed from the first interdigitated pattern of a row of alternating mandrels and filler-lines. The gaps created by the removal form a first pattern of trenches. The first pattern of trenches has a pitch 2P, and each trench of the first pattern of trenches has a width P.

In box 718, the first pattern of trenches is used as an etch mask in a pattern transfer etch that etches the first hardmask layer to form a pattern of first hardmask trenches. After forming the pattern of first hardmask trenches, the materials above the first hardmask layer (i.e., the mandrels and the filler lines) are removed.

In box 720, a first block mask is formed over the first hardmask layer. The first block mask covers a portion of the first hardmask trenches to form a first etch pattern over the layer to be patterned.

In box 722, the first etch pattern is transferred to the layer to be patterned to form a first group of final trenches. After forming the first group of final trenches, the first block mask is removed. After removing the first block mask, the first hardmask layer is removed.

As indicated in box 730, a second etch pattern is formed over the layer to be patterned by repeating the processing in boxes 710, 712, 714, 716, 718, and 720. However, the reticle used in forming the first pattern of mandrels and the reticle used in forming the first block mask are changed to form a second pattern of mandrels and a second block mask. The second pattern of mandrels is the first pattern of mandrels shifted by a distance P in a direction perpendicular to the mandrels.

In box 732, the second etch pattern is transferred to the layer to be patterned to form a second group of final trenches. After forming the second group of final trenches, the second block mask is removed. After removing the second block mask, the second hardmask layer is removed. The second group of final trenches and the first group of final trenches collectively form a pattern of final trenches. The pattern of final trenches has the final pitch, P, and each of the final trenches has the final width, P/2.

In this disclosure we have described two example embodiments of quadruple patterning with AS-SALELE. In both embodiments (flow A and flow B), the final design 100 comprises a pattern of P/2 wide parallel trenches arranged at a pitch P that is replicated in the layer to be patterned 450 by forming the pattern of final trenches 420 that also has the final pitch P and the final width P/2.

The interdigitated patterns, each comprising a row of mandrels and filler lines separated by anti-spacer material, may be formed on a substrate using commonly available materials and inexpensive spin-on processes and ovens that may be available in a lithography track.

The trench width, P/2, which is a critical dimension (CD), is defined by the thickness of the anti-spacer material formed self-aligned to mandrels. Thus, in quadruple patterning with AS-SALELE, the CD control is determined by the thickness control of the anti-spacer formation process. This provides an advantage of a tighter control than what is possible for a CD that is defined by photolithography. In various embodiments, the thickness of the anti-spacer material may be controlled to a 3-sigma variation of about 1 nm to about 2 nm.

Each of the mandrel patterns that has been used in the example embodiments of quadruple patterning with AS-SALELE is a row of mandrels arranged at a pitch of 4P. The patterns are printed using reticles that have line and space feature sizes of 1.5P and 2.5P. In sub-10 nm technology nodes, the final pitch, P, may be scaled down to a range where EUV lithography is used to form the pattern of mandrels. As known to persons skilled in the art, in EUV lithography, the patterning capability is often limited by stochastic effects. The larger resist feature sizes of 1.5P and 2.5P used in the embodiments of quadruple patterning with AS-SALELE provide the advantage of reducing the stochastic effects in EUV lithography.

Another advantage of quadruple patterning with anti-spacers formed self-aligned to mandrels, as opposed to quadruple patterning with spacers formed self-aligned to mandrels, is that the number of columns of trenches in the final design is constrained to be a multiple of two for quadruple patterning with anti-spacers instead of a being constrained to be a multiple of four for quadruple patterning with spacers.

Example 1. A method of patterning a substrate, where the method includes: forming first structures over a memorization layer, the first structures including a first row of lines that are parallel with each other and spaced apart from each other; executing a first anti-spacer formation process to form first trenches along sidewalls of the first structures and sidewalls of a first fill material, the first trenches defining a first etch pattern; transferring the first etch pattern into the memorization layer and removing materials above the memorization layer; forming second structures over the memorization layer, the second structures including a second row of lines that are parallel with each other and spaced apart, placement of the second row of lines being shifted relative to the first row of lines; executing a second anti-spacer formation process to form second trenches formed along sidewalls of the second structures and sidewalls of a second fill material, the second trenches defining a second etch pattern; and transferring the second etch pattern into the memorization layer and removing materials above the memorization layer.

Example 2. The method of example 1, further including, prior to transferring the first etch pattern into the memorization layer, forming a first block mask over the first trenches, the first block mask covering a portion of the first trenches, where the first etch pattern includes the first block mask.

Example 3. The method of one of examples 1 or 2, further including, prior to transferring the second etch pattern into the memorization layer, forming a second block mask over the second trenches, the second block mask covering a portion of the second trenches, where the second etch pattern includes the second block mask.

Example 4. The method of one of examples 1 to 3, further including: patterning a layer to be patterned disposed under the memorization layer based on the first etch pattern in the memorization layer and the second etch pattern in the memorization layer.

Example 5. The method of one of examples 1 to 4, where executing the first anti-spacer formation process includes: covering the first structures with a first overcoat; annealing the substrate to form a layer of an anti-spacer material along sides of the first structures, the layer of an anti-spacer material being formed from the first structures and first overcoat; and after forming the anti-spacer material, selectively removing the first overcoat to form a plurality of trenches; and filling the plurality of trenches with a filler material.

Example 6. The method of one of examples 1 to 5, where the first anti-spacer formation process includes an in-diffusion process, where a peripheral region of the first structures is converted to form the layer of the anti-spacer material.

Example 7. The method of one of examples 1 to 6, where filling the plurality of trenches includes: overfilling the plurality of trenches with the filler material; and exposing an outer surface of the anti-spacer material using a controlled recess etch step.

Example 8. The method of one of examples 1 to 7, where executing the first anti-spacer formation process includes: covering the first structures with a filler material; and annealing the substrate to form a layer of an anti-spacer material along sides of the first structures, the layer of an anti-spacer material being formed from the first structures and the filler material.

Example 9. The method of one of examples 1 to 8, where the first anti-spacer formation process includes an out-diffusion process, where a portion of the filler material is converted to form the layer of the anti-spacer material.

Example 10. The method of one of examples 1 to 9, where executing the first anti-spacer formation process further includes: exposing an outer surface of the layer of the anti-spacer material using a controlled recess etch process.

Example 11. The method of one of examples 1 to 10, where the first anti-spacer material removal process includes exposing the substrate to a solvent to selectively remove an anti-spacer material formed self-aligned to the first structures.

Example 12. The method of one of examples 1 to 11, where the solvent includes tetramethylammonium hydroxide (TMAH).

Example 13. A method of patterning a substrate, where the pattern includes a row of parallel final trenches having a first pitch, and the method includes: forming a first hardmask layer over a layer to be patterned in a substrate; forming, over the first hardmask layer, first stencil trenches having a pitch equal to double the first pitch, each trench of the first stencil trenches having a first width; forming a pattern of first hardmask trenches by etching the first hardmask layer using the first stencil trenches as an etch mask; forming a first block mask over the first hardmask layer, the first block mask covering a portion of the first hardmask trenches to form a first etch pattern over the layer to be patterned; transferring the first etch pattern to the layer to be patterned to form a first group of final trenches and removing the first block mask and the first hardmask layer; and transferring a second etch pattern to the layer to be patterned to form a second group of final trenches, the second group of final trenches and the first group of final trenches collectively forming a pattern of final trenches having the first pitch, and all of the final trenches having the same first width.

Example 14. The method of example 13, where the first width is equal to half the first pitch.

Example 15. The method of one of examples 13 or 14, where forming the first stencil trenches includes: forming, over the first hardmask layer, a first pattern of mandrels, the first pattern of mandrels being a row of mandrels having quadruple the first pitch; forming, from the first pattern of mandrels, a first interdigitated pattern of a row of alternating mandrels and filler-lines separated by an anti-spacer material, the filler-lines and the anti-spacer material being formed self-aligned to the mandrels, each mandrel and each filler-line of the first interdigitated pattern having a combined width equal to triple the first width; and selectively removing the anti-spacer material from the first interdigitated pattern to form the first stencil trenches.

Example 16. The method of one of examples 13 to 15, where selectively removing the anti-spacer material includes exposing the substrate to a solvent to remove the anti-spacer material from the first interdigitated pattern to form the first stencil trenches.

Example 17. The method of one of examples 13 to 16, where the solvent includes tetramethylammonium hydroxide (TMAH).

Example 18. The method of one of examples 13 to 17, where, prior to transferring the second etch pattern to the layer to be patterned, the method further includes: forming a second hardmask layer over the layer to be patterned in a substrate and the first group of final trenches; forming, over the first hardmask layer, second stencil trenches having a pitch equal to double the first pitch, each trench of the second stencil trenches having the first width, the second stencil trenches being formed self-aligned to mandrels of a second pattern of mandrels, the second pattern of mandrels being formed shifted relative to the first pattern of mandrels by a distance equal to the first pitch; forming a pattern of second hardmask trenches by etching the second hardmask layer using the second stencil trenches as an etch mask; and forming a second block mask over the second hardmask layer, the second block mask covering a portion of the second hardmask trenches to form a second etch pattern over the layer to be patterned.

Example 19. The method of one of examples 13 to 18, where forming the second stencil trenches includes: forming, over the second hardmask layer, a second pattern of mandrels, the second pattern of mandrels being shifted relative to the first pattern of mandrels by a distance equal to the first pitch; forming, from the second pattern of mandrels, a second interdigitated pattern using an anti-spacer formation process.

Example 20. A method of designing a reticle set, where the method includes: having a final design including a line-and-space (L/S) pattern having a final pitch; and decomposing the final design into a first reticle design and a second reticle design, the first reticle design and the second reticle design being part of a reticle design for the reticle set for quadruple patterning with anti-spacer self-aligned litho-etch-litho-etch (AS-SALELE) process, the first reticle design configured to pattern a first row of mandrels having a mandrel pitch equal to quadruple the final pitch, and the second reticle design configured to pattern a second row of mandrels having the same mandrel pitch, a placement of the second row of mandrels being shifted relative to the first row of mandrels by a distance equal to the final pitch in a direction parallel to the row of mandrels, the first reticle design and the second reticle design being configured to form a L/S pattern having the final pitch on a substrate.

Example 21. The method of example 20, where a space of the L/S pattern has a width equal to half the final pitch.

Example 22. The method of one of examples 20 or 21, further including: decomposing the final design into design for a first block reticle and a second block reticle, the first block reticle and the second block reticle being part of the reticle set, the first block reticle being configured to form a first block mask, the second block reticle being configured to form a second block mask.

Example 23. The method of one of examples 20 to 22, where the first block mask includes a plurality of first blocks configured to block a first hardmask trench configured to be formed on a side of one of the first row of mandrels, and where the second block mask includes a plurality of second blocks and is configured to block a second hardmask trench configured to be formed on a side of one of the second row of mandrels.

Example 24. The method of one of examples 20 to 23, where one of the first blocks is spaced from an adjacent one of the second blocks by a space that is larger than half the final pitch.

Example 25. The method of one of examples 20 to 24, where one of the first blocks is spaced from an adjacent one of the first blocks by a space that is larger than half the final pitch.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of patterning a substrate, the method comprising:
forming first structures over a memorization layer, the first structures including a first row of lines that are parallel with each other and spaced apart from each other;
executing a first anti-spacer formation process to form first trenches along sidewalls of the first structures and sidewalls of a first fill material, the first trenches defining a first etch pattern;
transferring the first etch pattern into the memorization layer and removing materials above the memorization layer;
forming second structures over the memorization layer, the second structures including a second row of lines that are parallel with each other and spaced apart, placement of the second row of lines being shifted relative to the first row of lines;
executing a second anti-spacer formation process to form second trenches formed along sidewalls of the second structures and sidewalls of a second fill material, the second trenches defining a second etch pattern; and
transferring the second etch pattern into the memorization layer and removing materials above the memorization layer.

2. The method of claim 1, further comprising, prior to transferring the first etch pattern into the memorization layer, forming a first block mask over the first trenches, the first block mask covering a portion of the first trenches, wherein the first etch pattern includes the first block mask.

3. The method of claim 2, further comprising, prior to transferring the second etch pattern into the memorization layer, forming a second block mask over the second trenches, the second block mask covering a portion of the second trenches, wherein the second etch pattern includes the second block mask.

4. The method of claim 1, wherein executing the first anti-spacer formation process comprises:
covering the first structures with a first overcoat;
annealing the substrate to form a layer of an anti-spacer material along sides of the first structures, the layer of an anti-spacer material being formed from the first structures and first overcoat; and
after forming the anti-spacer material, selectively removing the first overcoat to form a plurality of trenches; and
filling the plurality of trenches with a filler material.

5. The method of claim 4, wherein the first anti-spacer formation process comprises an in-diffusion process, wherein a peripheral region of the first structures is converted to form the layer of the anti-spacer material.

6. The method of claim 4, wherein filling the plurality of trenches comprises:
overfilling the plurality of trenches with the filler material; and
exposing an outer surface of the anti-spacer material using a controlled recess etch step.

7. The method of claim 1, wherein executing the first anti-spacer formation process comprises:
covering the first structures with a filler material; and
annealing the substrate to form a layer of an anti-spacer material along sides of the first structures, the layer of an anti-spacer material being formed from the first structures and the filler material.

8. The method of claim 7, wherein the first anti-spacer formation process comprises an out-diffusion process, wherein a portion of the filler material is converted to form the layer of the anti-spacer material.

9. The method of claim 7, wherein executing the first anti-spacer formation process further comprises:
exposing an outer surface of the layer of the anti-spacer material using a controlled recess etch process.

10. The method of claim 1, wherein the first anti-spacer material removal process comprises exposing the substrate to a solvent to selectively remove an anti-spacer material formed self-aligned to the first structures.

11. A method of patterning a substrate, the pattern comprising a row of parallel final trenches having a first pitch, the method comprising:
forming a first hardmask layer over a layer to be patterned in a substrate;
forming, over the first hardmask layer, first stencil trenches having a pitch equal to double the first pitch, each trench of the first stencil trenches having a first width;
forming a pattern of first hardmask trenches by etching the first hardmask layer using the first stencil trenches as an etch mask;
forming a first block mask over the first hardmask layer, the first block mask covering a portion of the first hardmask trenches to form a first etch pattern over the layer to be patterned;
transferring the first etch pattern to the layer to be patterned to form a first group of final trenches and removing the first block mask and the first hardmask layer; and
transferring a second etch pattern to the layer to be patterned to form a second group of final trenches, the second group of final trenches and the first group of final trenches collectively forming a pattern of final trenches having the first pitch, and all of the final trenches having the same first width.

12. The method of claim 11, wherein the first width is equal to half the first pitch.

13. The method of claim 11, wherein forming the first stencil trenches comprises:
forming, over the first hardmask layer, a first pattern of mandrels, the first pattern of mandrels being a row of mandrels having quadruple the first pitch;
forming, from the first pattern of mandrels, a first interdigitated pattern of a row of alternating mandrels and filler-lines separated by an anti-spacer material, the filler-lines and the anti-spacer material being formed self-aligned to the mandrels, each mandrel and each filler-line of the first interdigitated pattern having a combined width equal to triple the first width; and
selectively removing the anti-spacer material from the first interdigitated pattern to form the first stencil trenches.

14. The method of claim 11, wherein, prior to transferring the second etch pattern to the layer to be patterned, the method further comprises:
forming a second hardmask layer over the layer to be patterned in a substrate and the first group of final trenches;
forming, over the first hardmask layer, second stencil trenches having a pitch equal to double the first pitch, each trench of the second stencil trenches having the first width, the second stencil trenches being formed self-aligned to mandrels of a second pattern of mandrels, the second pattern of mandrels being formed shifted relative to the first pattern of mandrels by a distance equal to the first pitch;
forming a pattern of second hardmask trenches by etching the second hardmask layer using the second stencil trenches as an etch mask; and
forming a second block mask over the second hardmask layer, the second block mask covering a portion of the second hardmask trenches to form a second etch pattern over the layer to be patterned.

15. A method of designing a reticle set, the method comprising:
having a final design comprising a line-and-space (L/S) pattern having a final pitch; and
decomposing the final design into a first reticle design and a second reticle design, the first reticle design and the second reticle design being part of a reticle design for the reticle set for quadruple patterning with anti-spacer self-aligned litho-etch-litho-etch (AS-SALELE) process, the first reticle design configured to pattern a first row of mandrels having a mandrel pitch equal to quadruple the final pitch, and the second reticle design configured to pattern a second row of mandrels having the same mandrel pitch, a placement of the second row of mandrels being shifted relative to the first row of mandrels by a distance equal to the final pitch in a direction parallel to the row of mandrels, the first reticle design and the second reticle design being configured to form a L/S pattern having the final pitch on a substrate.

16. The method of claim 15, wherein a space of the L/S pattern has a width equal to half the final pitch.

17. The method of claim 15, further comprising:
decomposing the final design into design for a first block reticle and a second block reticle, the first block reticle and the second block reticle being part of the reticle set, the first block reticle being configured to form a first block mask, the second block reticle being configured to form a second block mask.

18. The method of claim 17, wherein the first block mask comprises a plurality of first blocks configured to block a first hardmask trench configured to be formed on a side of one of the first row of mandrels, and wherein the second block mask comprises a plurality of second blocks and is configured to block a second hardmask trench configured to be formed on a side of one of the second row of mandrels.

19. The method of claim 18, wherein one of the first blocks is spaced from an adjacent one of the second blocks by a space that is larger than half the final pitch.

20. The method of claim 18, wherein one of the first blocks is spaced from an adjacent one of the first blocks by a space that is larger than half the final pitch.
